(19) United States
(12) Patent Application Publication
(10) Pub. No.: US 2025/0357434 A1
(43) Pub. Date: Nov. 20, 2025

(54) ISOLATION CHIP AND METHOD FOR MANUFACTURING ISOLATION CHIP

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 19/290,952

(22) Filed: Aug. 5, 2025

Related U.S. Application Data
(63) Continuation of application No. PCT/JP2024/002348, filed on Jan. 26, 2024.

(30) Foreign Application Priority Data
Feb. 16, 2023 (JP) 2023-022510

(51) Int. Cl. H01L 25/07; H01L 23/00; H01L 23/14; H01L 23/495; H01L 23/498; H01L 23/538; H03K 17/691

(52) U.S. Cl. CPC H01L 25/072; H01L 23/147; H01L 23/4952; H01L 23/49551; H01L 23/49575; H01L 23/49827; H01L 23/5386; H01L 24/05; H01L 24/06; H01L 24/48; H03K 17/691; H01L 2224/05553; H01L 2224/05573; H01L 2224/0603; H01L 2224/0613; H01L 2224/06189; H01L 2224/4814; H01L 2924/13091; H03K 2217/0054; H03K 2217/0063; H03K 2217/0072; H03K 2217/0081

(57) ABSTRACT

An insulation chip includes a substrate, a first insulator, a first conductor, a second insulator, and a second conductor. The first conductor is embedded in the first insulator and exposed from the first insulator. The second insulator covers the first insulator and the first conductor. The second conductor is disposed on the second insulator. The first conductor, which includes an electrode pad, and the second conductor face each other in a thickness direction perpendicular to the upper surface of the first insulator. The second insulator includes insulating layers arranged on the first insulator and an exposing recess extending through the insulating layers to expose the electrode pad. The wall of the exposing recess is stepped such that the distance to the electrode pad increases from the upper surface of the first insulator toward the upper surface of the second insulator.

### CROSS-REFERENCE TO RELATED APPLICATIONS

This application is a continuation of, and claims the benefit of priority from International Application No. PCT/JP2024/002348, filed on Jan. 26, 2024, which claims the benefit of priority from Japanese Patent Application No. 2023-022510, filed on Feb. 16, 2023, the entire contents of each are incorporated herein by reference.

### BACKGROUND

### 1. Field

The present disclosure relates to an isolation chip and a method for manufacturing an isolation chip.

### 2. Description of Related Art

One known example of a signal transmission device is an insulation-type gate driver that applies gate voltage to the gate of a switching element such as a transistor. One known example of an isolation chip used for such a gate driver is a structure including a first coil and a second coil disposed in an element insulation layer facing each other in the thickness direction of the element insulation layer (refer to, for example, JP2016-28407A).

### BRIEF DESCRIPTION OF THE DRAWINGS

FIG. 1 is a circuit diagram schematically illustrating the configuration of a signal transmission device in accordance with a first embodiment.

FIG. 2 is a schematic plan view illustrating the configuration of the signal transmission device shown in FIG. 1.

FIG. 3 is a schematic cross-sectional view illustrating the configuration of the signal transmission device shown in FIG. 2.

FIG. 4 is a schematic perspective view illustrating an isolation chip of the signal transmission device shown in FIG. 3.

FIG. 5 is a schematic plan view of the isolation chip shown in FIG. 4.

FIG. 6 is a schematic plan view illustrating first coils of the isolation chip shown in FIG. 4.

FIG. 7 is a schematic plan view illustrating second coils of the isolation chip shown in FIG. 4.

FIG. 8 is a cross-sectional view taken along line 8-8 in FIG. 5.

FIG. 9 is a cross-sectional view taken along line 9-9 in FIG. 5.

FIG. 10 is a schematic cross-sectional view illustrating a manufacturing step of the isolation chip in accordance with the first embodiment.

FIG. 11 is a schematic cross-sectional view illustrating a manufacturing step following the step of FIG. 10.

FIG. 12 is a schematic cross-sectional view illustrating a manufacturing step following the step of FIG. 11.

FIG. 13 is a schematic cross-sectional view illustrating a manufacturing step following the step of FIG. 12.

FIG. 14 is a schematic cross-sectional view illustrating a manufacturing step following the step of FIG. 13.

FIG. 15 is a schematic cross-sectional view illustrating a manufacturing step following the step of FIG. 14.

FIG. 16 is a schematic cross-sectional view illustrating a manufacturing step following the step of FIG. 15.

FIG. 17 is a schematic cross-sectional view illustrating a manufacturing step following the step of FIG. 16.

FIG. 18 is a schematic cross-sectional view illustrating a manufacturing step following the step of FIG. 17.

FIG. 19 is a schematic cross-sectional view illustrating a manufacturing step following the step of FIG. 18.

FIG. 20 is a schematic cross-sectional view illustrating a manufacturing step following the step of FIG. 19.

FIG. 21 is a schematic cross-sectional view illustrating a manufacturing step following the step of FIG. 20.

FIG. 22 is a schematic cross-sectional view illustrating a modified example of the isolation chip.

FIG. 23 is a schematic plan view illustrating a modified example of the isolation chip.

FIG. 24 is a schematic plan view illustrating a modified example of the isolation chip.

FIG. 25 is a cross-sectional view taken along line 25-25 in FIG. 24.

FIG. 26 is a schematic plan view illustrating a modified example of the isolation chip.

FIG. 27 is a schematic plan view illustrating a modified example of the isolation chip.

FIG. 28 is a circuit diagram schematically illustrating the configuration of a signal transmission device in accordance with a second embodiment.

FIG. 29 is a schematic plan view illustrating an isolation chip of the signal transmission device shown in FIG. 28.

FIG. 30 is a cross-sectional view taken along line 30-30 in FIG. 29.

### DETAILED DESCRIPTION

Several embodiments of a signal transmission device and an isolation chip in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

This detailed description provides a comprehensive understanding of exemplary methods, apparatuses, and/or systems in accordance with the present disclosure. This detailed description is illustrative and is not intended to limit embodiments of the present disclosure or the application and use of the embodiments.

In this specification, the phrase “at least one of” as used in this disclosure means “one or more” of a desired choice. As one example, the phrase “at least one of” as used in this disclosure means “only one of the two choices” or “both of the two choices” in a case where the number of choices is two. In another example, the phrase “at least one of as used in this disclosure means “only one single choice” or “any combination of two or more choices” if the number of its choices is three or more.

### First Embodiment

### Overview of Signal Transmission Device

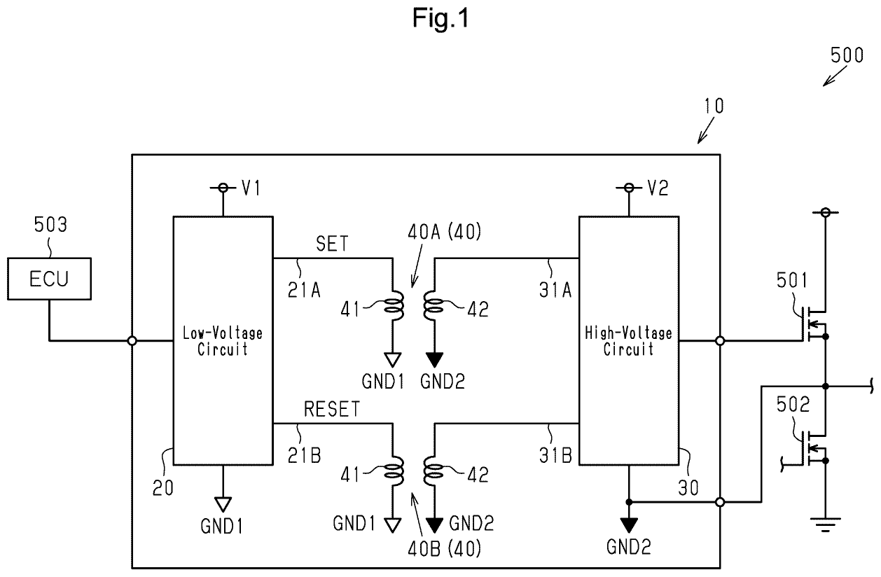

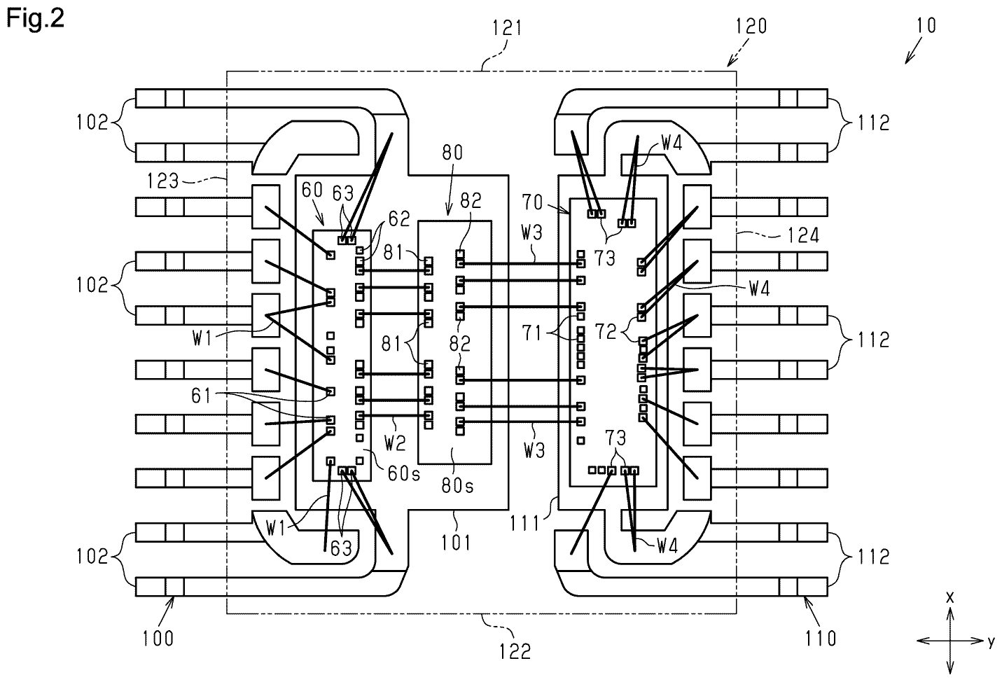

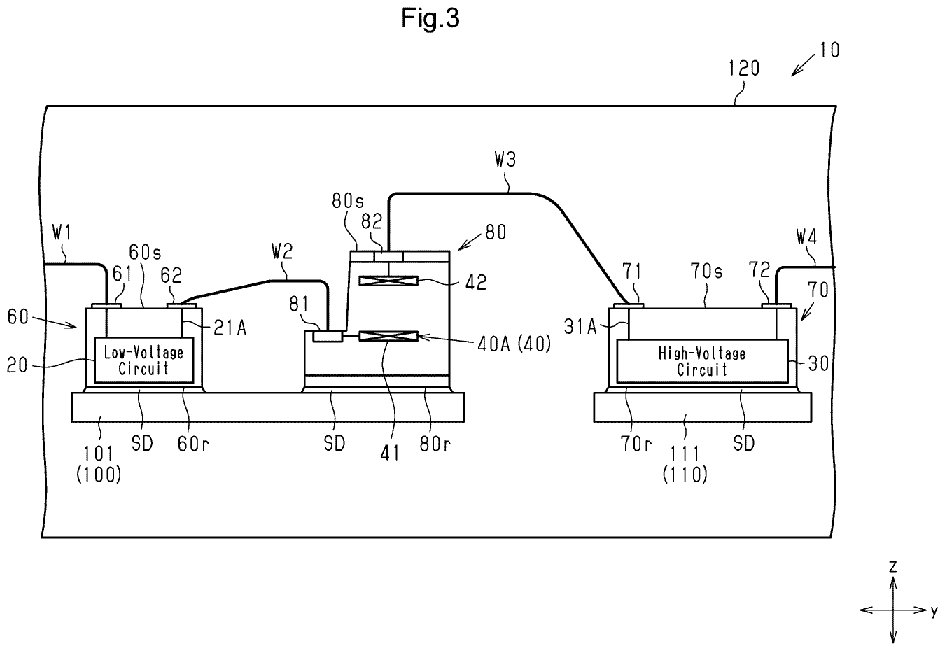

With reference to FIGS. 1 to 3, the configuration of a signal transmission device 10 in accordance with a first embodiment will now be described. FIG. 1 illustrates one example of the circuit configuration of the signal transmission device 10 in a simplified manner. FIG. 2 schematically illustrates one example of the planar structure inside the signal transmission device 10. FIG. 3 schematically illustrates one example of the cross-sectional structure inside a part of the signal transmission device 10. Hatching lines are not shown in FIG. 3 for the sake of brevity.

Referring to FIG. 1, in one example, the signal transmission device 10 is applied to an inverter device 500. The inverter device 500 includes control circuitry 503, which forms an electronic control unit (ECU), the signal transmission device 10, and switching elements 501 and 502. The signal transmission device 10 acts as a gate driver that drives the switching element 501 with the control circuitry 503. In FIG. 1, the signal transmission device 10 drives the switching element 501.

The switching element 501 is, for example, a high-side switching element connected to a drive power supply. The switching element 502 is a low-side switching element. The switching elements 501 and 502 may each be, for example, a transistor such as a Si metal-oxide-semiconductor field-effect transistor (Si MOSFET), a SiC MOSFET, or an insulated gate bipolar transistor (IGBT).

The signal transmission device 10 applies a drive voltage signal to the control terminal of the switching element 501. In the example described hereafter, SiC MOSFETs are used as the switching elements 501 and 502. The signal transmission device 10 is provided for each of the switching elements 501 and 502 to drive the corresponding one of the switching elements 501 and 502.

The signal transmission device 10 includes a low-voltage circuit 20, to which a first voltage V1 is applied, a high-voltage circuit 30, to which a second voltage V2 that is higher than the first voltage V1 is applied, and a transformer 40, which is located between the low-voltage circuit 20 and the high-voltage circuit 30. The transformer 40 connects the low-voltage circuit 20 and the high-voltage circuit 30. The first voltage V1 and the second voltage V2 are DC voltages.

The low-voltage circuit 20 and the high-voltage circuit 30 may be referred to as the primary-side circuit and the secondary-side circuit of the transformer 40. The low-voltage circuit 20 may be the primary-side circuit, and the high-voltage circuit 30 may be the secondary-side circuit. Alternatively, the high-voltage circuit 30 may be the primary-side circuit, and the high-voltage circuit 30 may be the secondary-side circuit. Further, the low-voltage circuit 20 and the high-voltage circuit 30 may each include the primary-side circuit and the secondary-side circuit.

In response to a control signal from the control circuitry 503, the signal transmission device 10 of the first embodiment is configured to transmit a signal from the low-voltage circuit 20 via the transformer 40 to the high-voltage circuit 30 and output a drive voltage signal from the high-voltage circuit 30.

The signal transmitted from the low-voltage circuit 20 toward the high-voltage circuit 30, that is, the signal output from the low-voltage circuit 20, is used, for example, to drive the switching element 501. Examples of such a drive signal include a set signal (SET) and a reset signal (RESET). The set signal is for transmitting a rising edge of a control signal from the control circuitry 503, and the reset signal is for transmitting a falling edge of a control signal from the control circuitry 503. The set signal and the reset signal are used to generate a drive voltage signal for the switching element 501. Thus, the set signal and the reset signal correspond to a first signal.

More specifically, the low-voltage circuit 20 is configured to be operated when the first voltage V1 is applied to the low-voltage circuit 20. The low-voltage circuit 20, which is electrically connected to the control circuitry 503, generates the set signal and the reset signal in response to a control signal from the control circuitry 503. For example, the low-voltage circuit 20 generates the set signal in response to a rising edge of a control signal and generates the reset signal in response to a falling edge of a control signal. The low-voltage circuit 20 transmits the generated set signal and reset signal toward the high-voltage circuit 30.

The high-voltage circuit 30 is configured to be operated when the second voltage V2 is applied to the high-voltage circuit 30. The high-voltage circuit 30 is electrically connected to the gate of the switching element 501. The high-voltage circuit 30 generates a drive voltage signal for driving the switching element 501, in response to the set signal and the reset signal received from the low-voltage circuit 20, and applies the drive voltage signal to the gate of the switching element 501. Thus, the high-voltage circuit 30 generates a drive voltage signal that is applied to the gate of the switching element 501 in response to the first signal output from the low-voltage circuit 20. The high-voltage circuit 30 generates a drive voltage signal for turning on the switching element 501 in response to the set signal and applies the drive voltage signal to the gate of the switching element 501. The high-voltage circuit 30 generates a drive voltage signal for turning off the switching element 501 in response to the reset signal and applies the drive voltage signal to the gate of the switching element 501. In this manner, the signal transmission device 10 on-off controls the switching element 501.

The high-voltage circuit 30 includes, for example, an RS type flip-flop circuit, which receives the set signal and the reset signal, and a driver, which generates a drive voltage signal in response to an output signal of the RS type flip-flop circuit. The specific circuit configuration of the high-voltage circuit 30 may be changed in any manner.

In the signal transmission device 10 of the first embodiment, the transformer 40 isolates the low-voltage circuit 20 from the high-voltage circuit 30. More specifically, the transformer 40 restricts the transmission of DC voltage between the low-voltage circuit 20 and the high-voltage circuit 30 but allows the transmission of various signals, such as the set signal and the reset signal between the low-voltage circuit 20 and the high-voltage circuit 30.

Thus, a state in which the low-voltage circuit 20 is isolated from the high-voltage circuit 30 refers to a state in which the transmission of DC voltage is restricted between the low-voltage circuit 20 and the high-voltage circuit 30 and the transmission of a signal is permitted between the low-voltage circuit 20 and the high-voltage circuit 30.

The dielectric breakdown voltage of the signal transmission device 10 is, for example, in the range from 2500 Vrms to 7500 Vrms, inclusive. The dielectric breakdown voltage of the signal transmission device 10 in the first embodiment is approximately 5000 Vrms. The dielectric breakdown voltage of the signal transmission device 10 is, however, not limited to any specific numerical value.

In the first embodiment, ground GND1 of the low-voltage circuit 20 is arranged independently from ground GND2 of the high-voltage circuit 30. The potential at the ground GND1 of the low-voltage circuit 20 is referred to as the first reference potential, and the potential at the ground GND2 of the high-voltage circuit 30 is referred to as the second reference potential. In this case, the first voltage V1 is derived from the first reference potential, and the second voltage V2 is derived from the second reference potential. The first voltage V1 is, for example, in the range from 4.5 V to 5.5 V, inclusive. The second voltage V2 is, for example, in the range from 9 V to 24 V, inclusive.

### Transformer

The transformer 40 will now be described in detail.

The signal transmission device 10 of the first embodiment includes two transformers 40 in correspondence with the two signals transmitted from the low-voltage circuit 20 toward the high-voltage circuit 30. One of the two transformers 40 will be referred to as the transformer 40A, and the other one of the two transformers 40 will be referred to as the transformer 40B. In an example, the transformer 40A is used to transmit the set signal. The transformer 40B is used to transmit the reset signal. In an example, the set signal and the reset signal may be a set signal and a reset signal of a reception circuit included in the high-voltage circuit 30.

The signal transmission device 10 includes a low-voltage signal line 21A, which connects the low-voltage circuit 20 and the transformer 40A, and a the low-voltage signal line 21B, which connects the low-voltage circuit 20 and the transformer 40B. Thus, the low-voltage signal line 21A transmits the set signal from the low-voltage circuit 20 to the transformer 40A. The low-voltage signal line 21B transmits the reset signal from the low-voltage circuit 20 to the transformer 40B.

The signal transmission device 10 includes a high-voltage signal line 31A, which connects the transformer 40A and the high-voltage circuit 30, and a high-voltage signal line 31B, which connects the transformer 40B and the high-voltage circuit 30. The high-voltage signal line 31A transmits the set signal from the transformer 40A to the high-voltage circuit 30. The high-voltage signal line 31B transmits the reset signal from the transformer 40B to the high-voltage circuit 30.

The transformer 40A transmits the set signal from the low-voltage circuit 20 to the high-voltage circuit 30. The transformer 40A electrically isolates the low-voltage circuit 20 from the high-voltage circuit 30. The transformer 40B transmits the reset signal from the low-voltage circuit 20 to the high-voltage circuit 30. The transformer 40B electrically isolates the low-voltage circuit 20 from the high-voltage circuit 30.

The transformers 40A and 40B each include a first coil 41 and a second coil 42. The first coil 41 and the second coil 42 are electrically isolated from each other and configured to be magnetically coupled to each other.

The first coils 41 of the transformers 40A and 40B are connected to the low-voltage circuit 20. For example, the first coil 41 of the transformer 40A has a first end electrically connected by the low-voltage signal line 21A to the low-voltage circuit 20, and the first coil 41 of the transformer 40A has a second end electrically connected to the ground GND1 of the low-voltage circuit 20. For example, the first coil 41 of the transformer 40B has a first end electrically connected by the low-voltage signal line 21B to the low-voltage circuit 20, and the first coil 41 of the transformer 40B has a second end electrically connected to the ground GND1 of the low-voltage circuit 20. The potential at the second end of each of the first coils 41 in the transformers 40A and 40B is referred to as the first reference potential. The first reference potential is, for example, 0 V.

The second coils 42 of the transformers 40A and 40B are connected to the high-voltage circuit 30. For example, the second coil 42 of the transformer 40A has a first end electrically connected by the high-voltage signal line 31A to the high-voltage circuit 30, and the second coil 42 of the transformer 40A has a second end electrically connected to the ground GND2 of the high-voltage circuit 30. For example, the second coil 42 of the transformer 40B has a first end electrically connected by the high-voltage signal line 31B to the high-voltage circuit 30, and the second coil 42 of the transformer 40B has a second end electrically connected to the ground GND2 of the high-voltage circuit 30. The potential at the second end of each of the second coils 42 of the transformers 40A and 40B is referred to as the second reference potential. The ground GND2 of the high-voltage circuit 30 is connected to the source of the switching element 501. Thus, when the inverter device 500 is driven, the second reference potential varies and may become, for example, 600 V or greater. For this reason, the dielectric breakdown voltage of the transformer 40 (40A, 40B) is set in accordance with the first reference potential, the second reference potential, and the like.

FIG. 2 is a plan view illustrating an example of the internal configuration of the signal transmission device 10. FIG. 1 shows the circuit configuration of the signal transmission device 10 in a simplified manner. Thus, the external terminals of the signal transmission device 10 shown in FIG. 2 are greater in number than the external terminals of the signal transmission device 10 shown in FIG. 1. The number of terminals of the signal transmission device 10 refers to the number of external electrodes that allow the signal transmission device 10 to be connected to electronic components located outside the signal transmission device 10, such as the control circuitry 503 and the switching element 501 (refer to FIG. 1). Further, the number of signal lines (number of wires W1 to W4, which will be described later) transmitting signals from the low-voltage circuit 20 to the high-voltage circuit 30 in the signal transmission device 10 illustrated in FIG. 2 is greater than the number of signal lines in the signal transmission device 10 illustrated in FIG. 1.

FIG. 3 is a cross-sectional view illustrating an example of the internal configuration of the signal transmission device 10. The cross-sectional view of FIG. 3 shows the internal configuration of signal transmission device 10 in a simplified manner. The cross-sectional structure of each of chips 60, 70, and 80 is shown in a simplified manner. Thus, the cross-sectional structure of the transformer chip 80 shown in FIG. 3 differs from the cross-sectional structure of the transformer chip 80 that will be described later.

As shown in FIG. 2, the signal transmission device 10 is a semiconductor device including a plurality of semiconductor devices in a single package, and is mounted on, for example, a circuit substrate arranged in the inverter device 500. The switching elements 501 and 502 are mounted on a mounting substrate that is separate from the above circuit substrate. A cooling device is attached to the mounting substrate.

The signal transmission device 10 is packaged as a small outline package (SOP) in the first embodiment. The signal transmission device 10 includes the low-voltage circuit chip 60, the high-voltage circuit chip 70, and the transformer chip 80, which are, for example, semiconductor chips. In an example, the low-voltage circuit chip 60 corresponds to a first circuit chip, and the high-voltage circuit chip 70 corresponds to a second circuit chip. The low-voltage circuit chip 60 may correspond to a first circuit chip, and the high-voltage circuit chip 70 may correspond to a second circuit chip. The transformer chip 80 is one example of an insulation chip.

The low-voltage circuit chip 60 is mounted on a low-voltage lead frame 100. The high-voltage circuit chip 70 is mounted on a high-voltage lead frame 110. Mold resin 120 encapsulates the chips 60, 70, and 80 and parts of the lead frames 100 and 110. In the first embodiment, the transformer chip 80 and the mold resin 120 correspond to an isolation module that isolates the low-voltage circuit 20 from the high-voltage circuit 30. In FIG. 2, the mold resin 120 is shown in double-dashed lines to aid understanding of the internal structure of the signal transmission device 10. The package of the signal transmission device 10 may be of any type.

The mold resin 120 is formed from an electrically insulative material. The resin may include, for example, epoxy resin. The resin may have, for example, a black color. The mold resin 120 has a rectangular form of which the thickness direction is a z-direction. The mold resin 120 has four resin side surfaces 121 to 124. More specifically, the mold resin 120 includes the resin side surfaces 121 and 122, which are the two end surfaces in an x-direction, and the resin side surfaces 123 and 124, which are the two end surfaces in a y-direction. The x-direction and the y-direction are perpendicular to the z-direction. The x-direction is perpendicular to the y-direction. The x-direction corresponds to a first direction. The y-direction corresponds to a second direction. In the description hereafter, a plan view refers to a view taken in the z-direction.

The low-voltage lead frame 100 and the high-voltage lead frame 110 are conductors and, in the first embodiment, formed from a material including copper (Cu), iron (Fe), or the like. The lead frames 100 and 110 extend from the inside to the outside of the mold resin 120.

The low-voltage lead frame 100 includes a low-voltage die pad 101, which is located in the mold resin 120, and low-voltage leads 102, which extend from the inside to the outside of the mold resin 120. Each low-voltage lead 102 forms an external terminal electrically connected to an external electric device such as the control circuitry 503 (refer to FIG. 1).

In the first embodiment, the low-voltage circuit chip 60 and the transformer chip 80 are both mounted on the low-voltage die pad 101. The low-voltage die pad 101 is disposed so that its central part in the y-direction is closer to the resin side surface 123 than the central part of the mold resin 120 in the y-direction is, in plan view. In the first embodiment, the low-voltage die pad 101 is not exposed from the mold resin 120. The low-voltage die pad 101 has a rectangular form in plan view so that its long sides extend in the x-direction and its short sides extend in the y-direction.

The low-voltage leads 102 are arranged separated from one another in the x-direction. The low-voltage lead 102 at each of the two ends of the array of the low-voltage leads 102 in the x-direction are integrated with the low-voltage die pad 101. A part of each low-voltage lead 102 projects out of the mold resin 120 from the resin side surface 123.

The high-voltage lead frame 110 includes a high-voltage die pad 111, which is located in the mold resin 120, and high-voltage leads 112, which extend from the inside to the outside of the mold resin 120. Each high-voltage lead 112 forms an external terminal electrically connected to an external terminal device such as the gate of the switching element 501 (refer to FIG. 1).

The high-voltage circuit chip 70 is mounted on the high-voltage die pad 111. The high-voltage die pad 111 is disposed so that its central part in the y-direction is closer to the resin side surface 124 than the low-voltage die pad 101 is, in plan view. In the first embodiment, the high-voltage die pad 111 is not exposed from the mold resin 120. The high-voltage die pad 111 has a rectangular form in plan view so that its long sides extend in the x-direction and its short sides extend in the y-direction.

The low-voltage die pad 101 is arranged separated from the high-voltage die pad 111 in the y-direction. Thus, the y-direction is the arrangement direction of the two die pads 101 and 111.

The dimensions of the low-voltage die pad 101 and the high-voltage die pad 111 in the y-direction are set in accordance with the size and quantity of the mounted semiconductor chips. In the first embodiment, the low-voltage circuit chip 60 and the transformer chip 80 are mounted on the low-voltage die pad 101, and the high-voltage circuit chip 70 is mounted on the high-voltage die pad 111. Thus, the y-direction dimension of the low-voltage die pad 101 is greater than the y-direction dimension of the high-voltage die pad 111.

The high-voltage leads 112 are arranged separated from one another in the x-direction. Two of the high-voltage leads 112 are integrated with the high-voltage die pad 111. A part of each high-voltage lead 112 projects out of the mold resin 120 from the resin side surface 124.

In the first embodiment, the high-voltage leads 112 are equal in number to the low-voltage leads 102. As shown in FIG. 2, the arrangement direction (x-direction) in which the low-voltage leads 102 are arranged next to one another and the high-voltage leads 112 are arranged next to one another is perpendicular to the arrangement direction (y-direction) of the low-voltage die pad 101 and the high-voltage die pad 111. There is no limitation to the number of the high-voltage leads 112 and the number of the low-voltage leads 102.

In the first embodiment, the low-voltage die pad 101 is supported by the low-voltage leads 102 integrated with the low-voltage die pad 101. The high-voltage die pad 111 is supported by the two high-voltage leads 112 integrated with the high-voltage die pad 111. Thus, the die pads 101 and 111 do not include suspension leads exposed from the resin side surfaces 121 and 122. This allows the isolation distance to be increased between the low-voltage lead frame 100 and the high-voltage lead frame 110.

The low-voltage circuit chip 60, the high-voltage circuit chip 70, and the transformer chip 80 are arranged separated from one another in the y-direction. The low-voltage circuit chip 60, the transformer chip 80, and the high-voltage circuit chip 70 are arranged in this order in the y-direction from the low-voltage leads 102 toward the high-voltage leads 112.

The low-voltage circuit chip 60 includes the low-voltage circuit 20 shown in FIG. 1. The low-voltage circuit chip 60 has a rectangular form in plan view and includes short sides and long sides. The low-voltage circuit chip 60 is mounted on the low-voltage die pad 101 so that the long sides extend in the x-direction and the short sides extend in the y-direction, in plan view. As shown in FIG. 3, the low-voltage circuit chip 60 includes a chip main surface 60s and a chip back surface 60r at opposite sides in the z-direction. The chip back surface 60r of the low-voltage circuit chip 60 is bonded by a conductive bonding material SD to the low-voltage die pad 101. The conductive bonding material SD may be solder, silver plate, or the like.

First electrode pads 61, second electrode pads 62, and third electrode pads 63 are formed on the chip main surface 60s of the low-voltage circuit chip 60. The first electrode pads 61, the second electrode pads 62, and the third electrode pads 63 are electrically connected to the low-voltage circuit 20.

The first electrode pads 61 are located on the chip main surface 60s closer to the low-voltage leads 102 than the central part of the chip main surface 60s in the y-direction is. The first electrode pads 61 are arranged next to one another in the x-direction. The second electrode pads 62 are located at the one of the two ends of the chip main surface 60s in the y-direction that is closer to the transformer chip 80. The second electrode pads 62 are arranged next to one another in the x-direction. The third electrode pads 63 are located at the two ends of the chip main surface 60s in the x-direction.

The high-voltage circuit chip 70 includes the high-voltage circuit 30 shown in FIG. 1. The high-voltage circuit chip 70 has a rectangular form in plan view and includes short sides and long sides. The high-voltage circuit chip 70 is mounted on the high-voltage die pad 111 so that the long sides extend in the x-direction and the short sides extend in the y-direction, in plan view. As shown in FIG. 3, the high-voltage circuit chip 70 includes a chip main surface 70s and a chip back surface 70r at opposite sides in the z-direction. The chip back surface 70r of the high-voltage circuit chip 70 is bonded by the conductive bonding material SD to the high-voltage die pad 111.

First electrode pads 71, second electrode pads 72, and third electrode pads 73 are formed on the chip main surface 70s of the high-voltage circuit chip 70. The first electrode pads 71, the second electrode pads 72, and the third electrode pads 73 are electrically connected to the high-voltage circuit 30.

The first electrode pads 71 are located at the one of the two ends of the chip main surface 70s in the y-direction that is closer to the transformer chip 80. The first electrode pads 71 are arranged next to one another in the x-direction. The second electrode pads 72 are located at the one of the two ends of the chip main surface 70s in the y-direction that is farther from the transformer chip 80. Thus, the second electrode pads 72 are located at the one of the two ends of the chip main surface 70s in the y-direction that is closer to the high-voltage leads 112. The second electrode pads 72 are arranged next to one another in the x-direction. The third electrode pads 73 are located at the two ends of the chip main surface 70s in the x-direction.

The transformer chip 80 includes the transformer 40 (40A, 40B) shown in FIG. 1. The transformer chip 80 has a rectangular form in plan view and includes short sides and long sides. In the first embodiment, the transformer chip 80 is mounted on the low-voltage die pad 101 so that the long sides extend in the x-direction and the short sides extend in the y-direction, in plan view.

The transformer chip 80 is located next to the low-voltage circuit chip 60 in the y-direction. The transformer chip 80 is located closer to the high-voltage circuit chip 70 than the low-voltage circuit chip 60 is. Thus, the transformer chip 80 is located between the low-voltage circuit chip 60 and the high-voltage circuit chip 70 in the y-direction.

As shown in FIG. 3, the transformer chip 80 includes a chip main surface 80s and a chip back surface 80r at opposite sides in the z-direction. The chip back surface 80r of the transformer chip 80 is bonded by the conductive bonding material SD to the low-voltage die pad 101.

As shown in FIG. 2, the transformer chip 80 includes first electrode pads 81 and second electrode pads 82. The first electrode pads 81 are located at the one of the two ends of the transformer chip 80 in the y-direction that is closer to the low-voltage circuit chip 60. The first electrode pads 81 are arranged next to one another in the x-direction. The second electrode pads 82 are located proximate to the central part of the transformer chip 80 in the y-direction. The second electrode pads 82 are arranged next to one another in the x-direction.

As shown in FIG. 3, the second electrode pads 82 are disposed on the chip main surface 80s of the transformer chip 80. The first electrode pads 81 are located between the chip back surface 80r and the chip main surface 80s on the transformer chip 80. In an example, the first electrode pads 81 are located at the same position as the first coil 41 in the z-direction.

As shown in FIG. 2, the part of the low-voltage die pad 101 and the part of the high-voltage die pad 111 where the lead frames 100 and 110 are the closest to each other have to be distanced from each other to set the dielectric breakdown voltage of the signal transmission device 10 at a predetermined dielectric breakdown voltage. Thus, the distance between the high-voltage circuit chip 70 and the transformer chip 80 is greater than the distance between the low-voltage circuit chip 60 and the transformer chip 80, in plan view.

Wires W1 to W4 are connected to the low-voltage circuit chip 60, the transformer chip 80, and the high-voltage circuit chip 70. The wires W1 to W4 are bonding wires formed by a wire bonding device, and are conductors from a material including, for example, gold (Au), aluminum (Al), copper (Cu), or the like.

The low-voltage circuit chip 60 is electrically connected by the wires W1 to the low-voltage lead frame 100. More specifically, the first electrode pads 61 and the third electrode pads 63 of the low-voltage circuit chip 60 are connected to the low-voltage leads 102 by the wires W1. The third electrode pads 63 of the low-voltage circuit chip 60 are connected by the wires W1 to the two low-voltage leads 102 integrated with the low-voltage die pad 101. This electrically connects the low-voltage circuit 20 to the low-voltage leads 102 (those external electrodes of signal transmission device 10 electrically connected to control circuitry 503). In the present embodiment, the two low-voltage leads 102 integrated with the low-voltage die pad 101 form ground terminals, and the wires W1 electrically connect the low-voltage circuit 20 and the low-voltage die pad 101. Thus, the potential at the low-voltage die pad 101 is the same as that at the ground GND1 of the low-voltage circuit 20.

The high-voltage circuit chip 70 is electrically connected by the wires W4 to the high-voltage leads 112 of the high-voltage lead frame 110. More specifically, the second electrode pads 72 and the third electrode pads 73 of the high-voltage circuit chip 70 are connected to the high-voltage leads 112 by the wires W4. This electrically connects the high-voltage circuit 30 to the high-voltage leads 112 (those external electrodes of signal transmission device 10 electrically connected to switching element 501 and the like). In the first embodiment, the two high-voltage leads 112 integrated with the high-voltage die pad 111 form ground terminals, and the wires W4 electrically connect the high-voltage circuit 30 and the high-voltage die pad 111. Thus, the potential at the high-voltage die pad 111 is the same as that at the ground GND2 of the high-voltage circuit 30.

The transformer chip 80 is connected to the low-voltage circuit chip 60 by the wires W2. The transformer chip 80 is connected to the high-voltage circuit chip 70 by the wires W3. More specifically, the first electrode pads 81 of the transformer chip 80 are connected to the second electrode pads 62 of the low-voltage circuit chip 60 by the wires W2. The second electrode pads 82 of the transformer chip 80 are connected to the first electrode pads 71 of the high-voltage circuit chip 70 by the wires W3.

The first coils 41 of the transformer 40A and the transformer 40B (refer to FIG. 1) are both electrically connected by the wires W2, the low-voltage circuit chip 60, and the like to the ground GND1 of the low-voltage circuit 20. The second coils 42 of the transformer 40A and the transformer 40B (refer to FIG. 1) are both electrically connected by the wires W3, the high-voltage circuit chip 70, and the like to the ground GND2 of the high-voltage circuit 30.

### Configuration of Transformer Chip

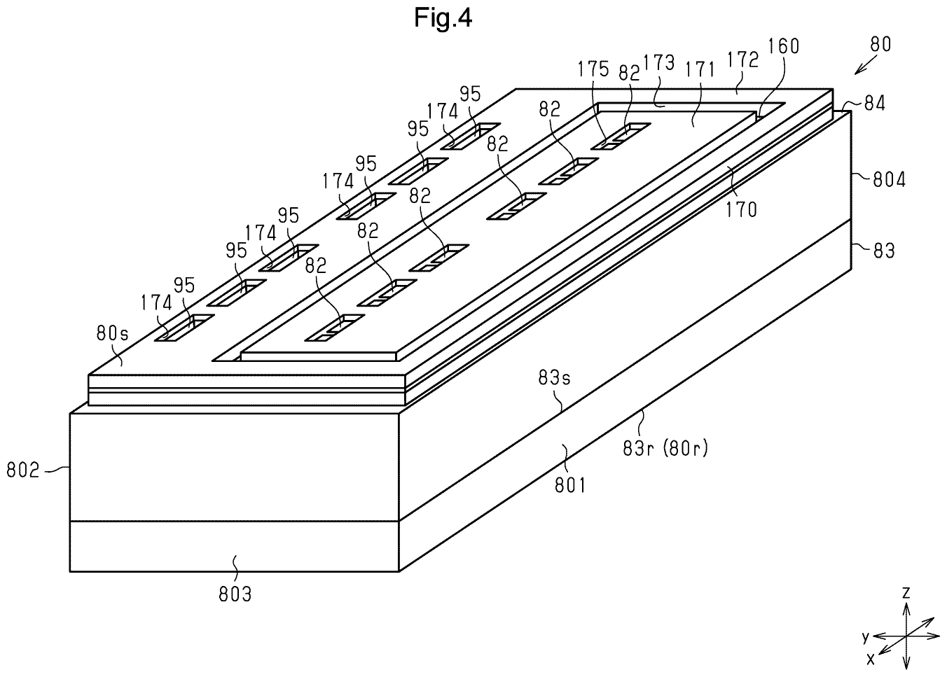

An example of the configuration of the transformer chip 80 will now be described with reference to FIGS. 4 to 9.

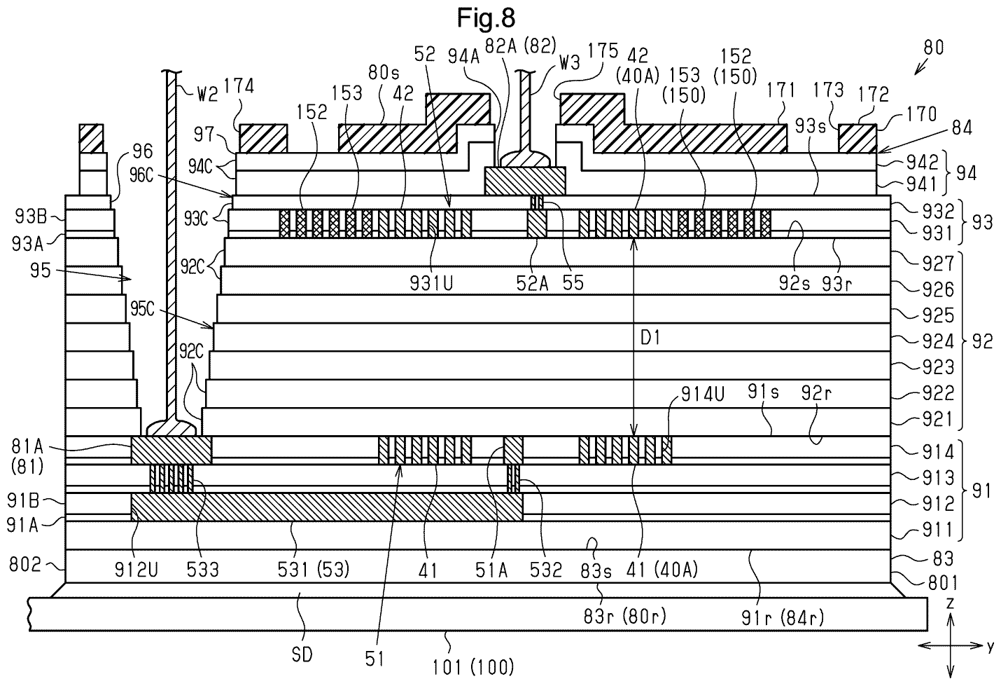

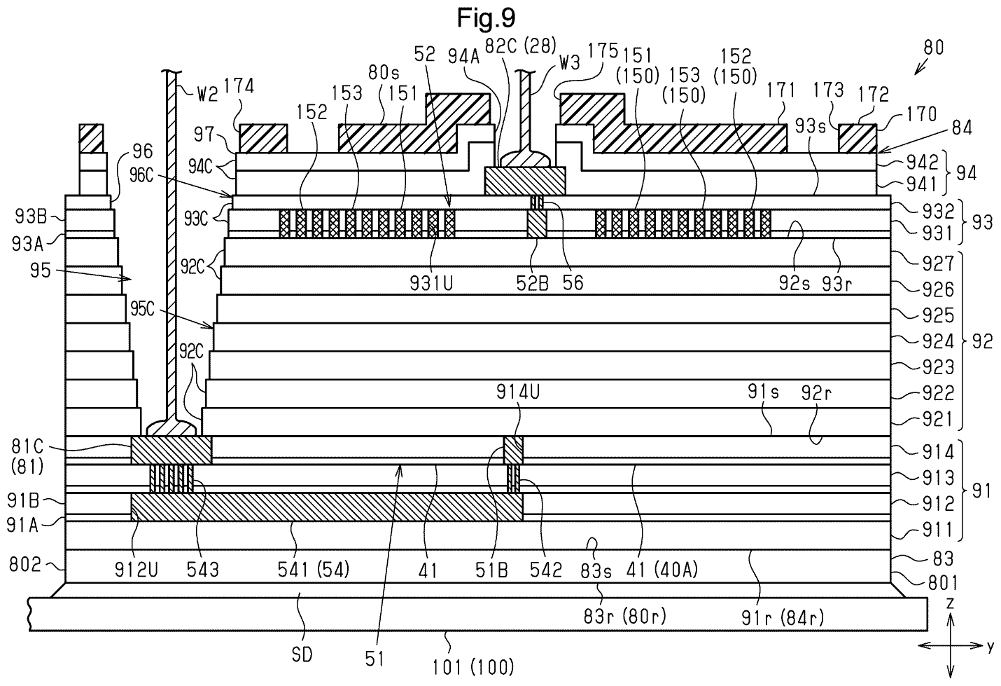

In the description hereafter, the direction extending from the chip back surface 80r toward the chip main surface 80s of the transformer chip 80, which are shown in FIGS. 8 and 9, will be referred to as the upward direction, and the direction extending from the chip main surface 80s toward the chip back surface 80r will be referred to as the downward direction. FIG. 4 is a perspective view showing the transformer chip 80.

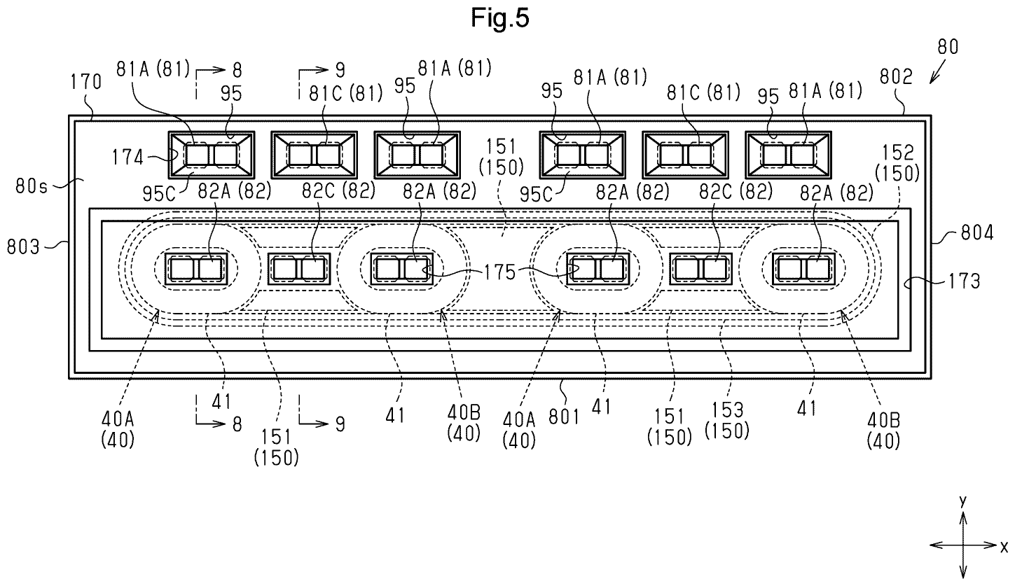

FIG. 5 is a plan view of the transformer chip 80. In FIG. 5, the transformers 40A and 40B, the first electrode pads 81, the second electrode pads 82, and dummy patterns 150 are depicted in broken lines for clarity.

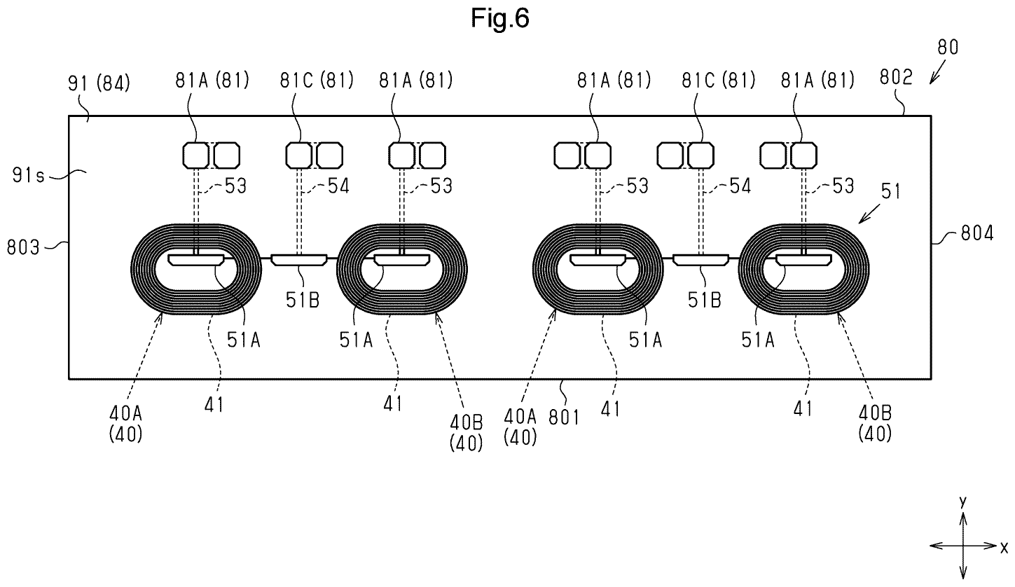

FIG. 6 is a cross-sectional view of the transformer chip 80 taken along an xy plane at where the first coils 41 are located in the z-direction and shows the relationship of the first coils 41.

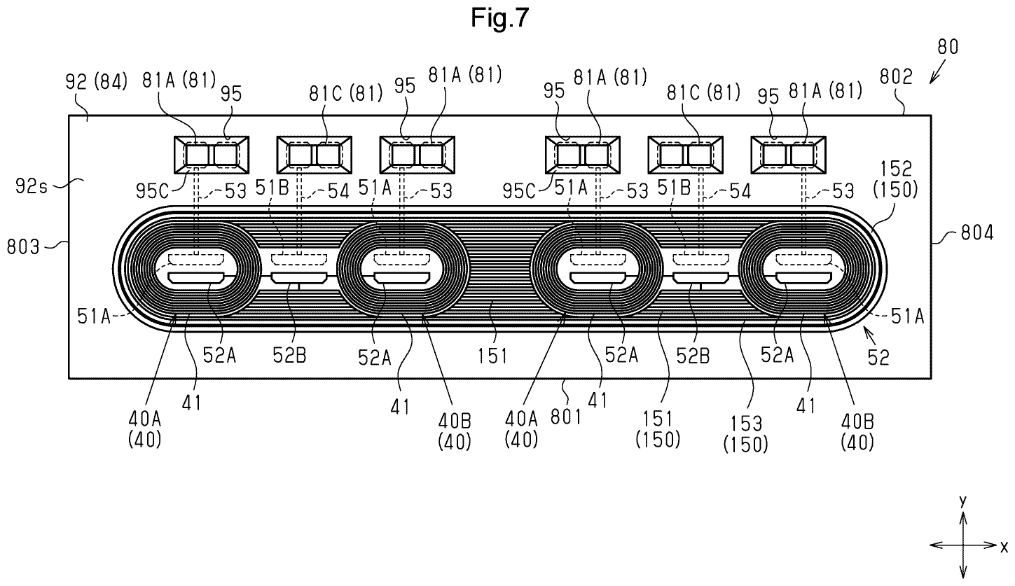

FIG. 7 is a cross-sectional view of the transformer chip 80 taken along an xy plane at where the second coils 42 are located in the z-direction and shows the relationship of the second coils 42. Hatching lines are not shown in FIGS. 6 and 7 for the sake of simplicity.

FIG. 8 is a cross-sectional view of the transformer chip 80 taken along line 8-8 in FIG. 5 and shows the cross-sectional structure of an insulator 84, the first coil 41, the second coil 42, the dummy pattern 150, the first electrode pad 81 (first pad 81A), and the second electrode pad 82 (third pad 82A). FIG. 9 is a cross-sectional view of the transformer chip 80 taken along line 9-9 in FIG. 5 and shows the insulator 84, the dummy pattern 150, the first electrode pad 81 (second pads 81C), and the second electrode pad 82 (fourth pad 82C).

As shown in FIG. 5, the transformer chip 80 includes two pairs of the transformers 40A and 40B. More specifically, the transformer chip 80 is a semiconductor chip incorporating the two pairs of the transformers 40A and 40B. The transformer chip 80 is separate from the low-voltage circuit chip 60 and the high-voltage circuit chip 70 (refer to FIG. 2).

The transformers 40A and 40B are located proximate to the central part of the chip main surface 80s in the y-direction, in plan view. In an example, the first electrode pads 81 are located at positions separated from the transformers 40A and 40B in plan view. The first electrode pads 81 and the second electrode pads 82 are electrically connected to the transformers 40A and 40B.

Each pair of the transformers 40A and 40B have the same structure. Further, the transformer 40B has the same structure as the transformer 40A. Thus, the structure of the transformer 40A will be described, and the structure of the transformer 40B will not be described.

As shown in FIGS. 4 and 5, the transformer chip 80 includes four chip side surfaces 801, 802, 803, and 804 extending perpendicular to both the chip main surface 80s and the chip back surface 80r. The chip side surfaces 801, 802, 803, and 804 extend between the chip main surface 80s and the chip back surface 80r in the z-direction. The chip side surfaces 801 and 802 are the two end surfaces of the transformer chip 80 in the y-direction, and the chip side surfaces 803 and 804 are the two end surfaces of the transformer chip 80 in the x-direction. In plan view, the chip side surfaces 801 and 802 are the long sides of the transformer chip 80, and the chip side surfaces 803 and 804 are the short sides of the transformer chip 80. In the first embodiment, the chip side surface 801 is closer than the chip side surface 802 to the high-voltage circuit chip 70 (refer to FIG. 2), and the chip side surface 802 is closer than the chip side surface 801 to the low-voltage circuit chip 60 (refer to FIG. 2).

As shown in FIGS. 4, 8, and 9, the transformer chip 80 includes a substrate 83 and the insulator 84 formed on the substrate 83.

The substrate 83 is formed by, for example, a semiconductor substrate. In the first embodiment, the substrate 83 is formed from a material including silicon (Si). The Si substrate used as the substrate 83 may be a semiconductor substrate formed from a monocrystalline intrinsic semiconductor material, a p-type semiconductor substrate including acceptor impurities, an n-type semiconductor substrate including donor impurities, or the like.

The substrate 83 may be a semiconductor substrate of a wide bandgap semiconductor or a compound semiconductor. Further, instead of a semiconductor substrate, the substrate 83 may be an insulative substrate formed from a material including glass. A wide bandgap semiconductor is a semiconductor substrate having a bandgap of 2.0 eV or greater. The wideband gap semiconductor may be silicon carbide (SiC), gallium nitride (GaN), gallium oxide (Ga₂O3₃), or the like. A compound semiconductor may be a III-V compound semiconductor. The compound semiconductor may contain at least one of aluminum nitride (AlN), indium nitride (InN), GaN, and gallium arsenide (GaAs).

The substrate 83 includes a substrate upper surface 83s and a substrate lower surface 83r at opposite sides in the z-direction. The substrate lower surface 83r defines the chip back surface 80r of the transformer chip 80.

The substrate 83 is quadrangular (rectangular in the first embodiment) as viewed in the z-direction.

As shown in FIGS. 8 and 9, the insulator 84 includes a first insulator 91, a second insulator 92, and a third insulator 93 that are disposed on the substrate upper surface 83s of the substrate 83 in the z-direction.

The first insulator 91 includes a first upper surface 91s and a first lower surface 91r. The first upper surface 91s faces the same direction as the substrate upper surface 83s of the substrate 83. The first lower surface 91r and the first upper surface 91s face opposite directions. The first lower surface 91r faces the substrate upper surface 83s of the substrate 83. The first lower surface 91r is in contact with the substrate upper surface 83s of the substrate 83. The first insulator 91 is formed on the substrate upper surface 83s of the substrate 83.

The first insulator 91 includes first insulation layers 911 to 914 disposed in the z-direction. The lowermost first insulation layer 911 is in contact with the substrate upper surface 83s of the substrate 83. The lowermost first insulation layer 911 directly covers the substrate upper surface 83s of the substrate 83. The lowermost first insulation layer 911 defines the first lower surface 91r of the first insulator 91. The uppermost first insulation layer 914 defines the first upper surface 91s of the first insulator 91.

The first insulation layers 912 to 914 each include a first insulation film 91A and a second insulation film 91B on the first insulation film 91A. The first insulation film 91A is a thin film and is, for example, an etching stopper layer. The first insulation film 91A is formed from a material including silicon nitride (SIN), SiC, silicon carbonitride (SiCN), or the like. In the first embodiment, the first insulation film 91A is formed from a material including SiN. The second insulation film 91B is, for example, an interlayer insulation film. The second insulation film 91B is formed from a material including silicon oxide (SiO₂). The second insulation film 91B is thicker than the first insulation film 91A. The first insulation film 91A may have a thickness that is greater than or equal to 100 nm and less than 1000 nm. The second insulation film 91B may have a thickness in the range from 1000 nm to 3000 nm, inclusive. The thickness of the first insulation film 91A is, for example, approximately 300 nm, and the thickness of the second insulation film 91B is, for example, approximately, 2000 nm.

The lowermost first insulation layer 911, which is in contact with the substrate upper surface 83s of the substrate 83, is formed by the second insulation film 91B. That is, the lowermost first insulation layer 911 is formed from a material including SiO₂. The lowermost first insulation layer 911 is thinner than the other first insulation layers 912 to 914. For example, the thickness of the lowermost first insulation layer 911 is greater than or equal to the thickness of the first insulation film 91A and less than or equal to the thickness of the second insulation film 91B. The lowermost first insulation layer 911 may have any thickness. In an example, the thickness of the lowermost first insulation layer 911 may be greater than the thickness of the second insulation film 91B, and may be greater than or equal to the thickness of each of the first insulation layers 912 to 914 formed by the first insulation film 91A and the second insulation film 91B.

The second insulator 92 includes a second upper surface 92s and a second lower surface 92r. The second upper surface 92s faces the same direction as the first upper surface 91s of the first insulator 91. The second lower surface 92r and the second upper surface 92s face opposite directions. The second lower surface 92r faces the first upper surface 91s of the first insulator 91. The second lower surface 92r is in contact with the first upper surface 91s of the first insulator 91. The second insulator 92 is formed on the first upper surface 91s of the first insulator 91.

The second insulator 92 includes second insulation layers 921 to 927 disposed in the z-direction. The lowermost second insulation layer 921 is in contact with the first upper surface 91s of the first insulator 91. Thus, the second insulator 92 includes the second insulation layers 921 to 927 disposed on the first upper surface 91s of the first insulator 91 in the z-direction (thickness direction). The lowermost second insulation layer 921 defines the second lower surface 92r of the second insulator 92. The lowermost second insulation layer 921 directly covers the first upper surface 91s of the first insulator 91. The uppermost second insulation layer 927 defines the second upper surface 92s of the second insulator 92. The second insulation layers 921 to 927 are formed from a material including SiO₂.

The third insulator 93 includes a third upper surface 93s and a third lower surface 93r. The third upper surface 93s faces the same direction as the second upper surface 92s of the second insulator 92. The third lower surface 93r and the third upper surface 93s face opposite directions. The third lower surface 93r faces the second upper surface 92s of the second insulator 92. The third lower surface 93r is in contact with the second upper surface 92s of the second insulator 92. The third insulator 93 is formed on the second upper surface 92s of the second insulator 92.

The third insulator 93 includes third insulation layers 931 and 932 disposed in the z-direction. For example, the third insulator 93 of the first embodiment includes the two third insulation layers 931 and 932. The lowermost third insulation layer 931 is in contact with the second upper surface 92s of the second insulator 92. The lowermost third insulation layer 931 defines the third lower surface 93r of the third insulator 93. The lowermost third insulation layer 931 directly covers the second upper surface 92s of the second insulator 92. The uppermost third insulation layer 932 defines the third upper surface 93s of the third insulator 93.

The lowermost third insulation layer 931 includes a first insulation film 93A and a second insulation film 93B on the first insulation film 93A. The first insulation film 93A is a thin film and is, for example, an etching stopper layer. The first insulation film 93A is formed from a material including SIN, SiC, SiCN, or the like. In the first embodiment, the first insulation film 93A is formed from a material including SiN. The second insulation film 93B is, for example, an interlayer insulation film. The second insulation film 93B is formed from a material including SiO₂. The second insulation film 93B is thicker than the first insulation film 93A. The first insulation film 93A may have a thickness that is greater than or equal to 100 nm and less than 1000 nm. The second insulation film 93B may have a thickness in the range from 1000 nm to 3000 nm, inclusive. The thickness of the first insulation film 93A is, for example, approximately 300 nm, and the thickness of the second insulation film 93B is, for example, approximately, 2000 nm.

The uppermost third insulation layer 932 is formed by the second insulation film 93B. The uppermost third insulation layer 932 is formed from a material including SiO₂. The uppermost third insulation layer 932 is thinner than the other third insulation layer 931. For example, the thickness of the uppermost third insulation layer 932 is greater than or equal to the thickness of the first insulation film 93A and less than or equal to the thickness of the second insulation film 93B. The uppermost third insulation layer 932 may have any thickness. In an example, the thickness of the uppermost third insulation layer 932 may be greater than the thickness of the second insulation film 93B, and may be greater than or equal to the thickness of the third insulation layer 931 formed by the first insulation film 93A and the second insulation film 93B.

### First Conductor, Second Conductor

As shown in FIGS. 6 to 9, the transformer chip 80 includes a first conductor 51 and a second conductor 52. The first conductor 51 and the second conductor 52 are embedded in the insulator 84.

The first conductor 51 is embedded in the first insulator 91. The second conductor 52 is embedded in the third insulator 93.

### First Conductor, First Electrode Pads, First Coil

As shown in FIGS. 8 and 9, the first conductor 51 is formed by a conductive layer embedded in one of the insulation layers of the first insulator 91. Among the insulation layers 911 to 914 of the first insulator 91, the first conductor 51 is formed in the uppermost insulation layer 914. The uppermost insulation layer 914 defines the first upper surface 91s of the first insulator 91. The first conductor 51 is embedded in the first insulator 91 and exposed from the first upper surface 91s.

The first insulation layer 914, in which the first conductor 51 is embedded, includes a groove 914U extending through both of the first insulation film 91A and the second insulation film 91B in the z-direction. The first conductor 51 is embedded in the groove 914U of the insulation layer 914. The uppermost first insulation layer 914, in which the first conductor 51 is embedded, is covered by the second insulator 92 in the z-direction.

As shown in FIGS. 6, 8, and 9, the first conductor 51 includes the first coil 41, the first electrode pads 81, an inner end wiring 51A, and an outer end wiring 51B. The first coil 41 corresponds to a first main body.

As shown in FIG. 6, the first coil 41 has the form of an elliptical spiral in plan view. The first coil 41 is formed from a material including one or more of titanium (Ti), titanium nitride (TiN), Au, Ag, Cu, Al, and tungsten (W). The inner end wiring 51A is disposed at the inner side of the first coil 41. The outer end wiring 51B is disposed at the outer side of the first coil 41. The first coil 41 includes a first end and a second end at the opposite side of the first end. The first end of the first coil 41 is electrically connected to the inner end wiring 51A, and the second end of the first coil 41 is electrically connected to the outer end wiring 51B.

The inner end wiring 51A and the outer end wiring 51B are formed from a material including one or more of Ti, TiN, Au, Ag, Cu, Al, and W. The outer end wiring 51B is located between the first coil 41 of the transformer 40A and the first coil 41 of the transformer 40B. The outer end wiring 51B is shared by the first coils 41 of the transformers 40A and 40B. An outer end wiring may be provided for each of the first coils 41 of the transformers 40A and 40B.

As shown in FIGS. 5 to 7, the first electrode pads 81 include the first pads 81A and the second pads 81C. The first electrode pads 81 include two first pads 81A and two second pads 81C that are connected to the first coil 41 of the transformer 40A. In the same manner, the first electrode pads 81 include two first pads 81A and two second pads 81C that are connected to the first coil 41 of the transformer 40B. The two first pads 81A are arranged next to each other in the x-direction. The two second pads 81C are arranged next to each other in the x-direction.

As shown in FIGS. 6 and 8, the inner end wiring 51A is electrically connected by an inner interconnection 53 to the first pads 81A of the first electrode pads 81.

The inner interconnection 53 includes an inner wiring portion 531 and vias 532 and 533.

As shown in FIG. 8, the inner wiring portion 531 is disposed closer to the first pad 81A, the first coil 41, and the inner end wiring 51A of the first conductor 51 than the substrate 83 is. The inner wiring portion 531 is formed in the first insulation layer 912 that sandwiches the first insulation layer 913 with the first insulation layer 914, in which the first conductor 51 is embedded. The inner wiring portion 531 is embedded in a groove 912U, which is formed in the first insulation layer 912. The via 532 extends through the first insulation layer 913 and electrically connects the inner end wiring 51A and the inner wiring portion 531. The via 533 extends through the first insulation layer 913 and electrically connects the first pad 81A and the inner wiring portion 531.

As shown in FIGS. 6 and 9, the outer end wiring 51B is electrically connected by an outer interconnection 54 to the second pad 81C of the first electrode pads 81.

The outer interconnection 54 includes an outer wiring portion 541, which extends in the y-direction, and vias 542 and 543.

The outer wiring portion 541 is disposed closer to the second pad 81C, the first coil 41, and the outer end wiring 51B of the first conductor 51 than the substrate 83 is. The outer wiring portion 541 is formed in the first insulation layer 912 that sandwiches the first insulation layer 913 with the first insulation layer 914, in which the first conductor 51 is embedded. The outer wiring portion 541 is embedded in the groove 912U, which is formed in the first insulation layer 912. The via 542 extends through the first insulation layer 913 and electrically connects the outer end wiring 51B and the outer wiring portion 541. The via 543 extends through the first insulation layer 913 and electrically connects the second pad 81C and the outer wiring portion 541.

### Second Conductor, Second Coil

As shown in FIGS. 8 and 9, the second conductor 52 is formed by a conductive layer embedded in one of the insulation layers of the third insulator 93. Among the third insulation layers 931 and 932 of the third insulator 93, the second conductor 52 is formed in the lowermost third insulation layer 931. The lowermost insulation layer 931 defines the third lower surface 93r of the third insulator 93. The second conductor 52 is embedded in the third insulator 93 and exposed from the third lower surface 93r.

The third insulator 93 is formed on the second upper surface 92s of the second insulator 92. Thus, the second conductor 52 is formed on the second upper surface 92s of the second insulator 92. Further, the second conductor 52 is covered by the third insulator 93.

The third insulation layer 931, in which the second conductor 52 is embedded, includes a groove 931U, which extends through both the first insulation film 93A and the second insulation film 93B in the z-direction. The second conductor 52 is embedded in the groove 931U of the insulation layer 931. The lowermost third insulation layer 931, in which the second conductor 52 is embedded, is formed on the second upper surface 92s of the second insulator 92 in the z-direction.

As shown in FIGS. 7, 8, and 9, the second conductor 52 includes the second coil 42, an inner end wiring 52A, and an outer end wiring 52B. The second coil 42 corresponds to a second main body.

As shown in FIG. 7, the second first coil 42 has the form of an elliptical spiral in plan view. The second coil 42 is formed from a material including one of more of Ti, TiN, Au, Ag, Cu, Al, and W. The inner end wiring 52A is disposed at the inner side of the second coil 42. The outer end wiring 52B is disposed at the outer side of the second coil 42. The second coil 42 includes a first end and a second end at the opposite side of the first end. The first end of the second coil 42 is electrically connected to the inner end wiring 52A, and the second end of the second coil 42 is electrically connected to the outer end wiring 52B.

The inner end wiring 52A and the outer end wiring 52B are formed from a material including one or more of Ti, TiN, Au, Ag, Cu, Al, and W. The outer end wiring 52B is located between the second coil 42 of the transformer 40A and the second coil 42 of the transformer 40B. The outer end wiring 52B is shared by the second coils 42 of the transformers 40A and 40B. An outer end wiring may be provided for each of the second coils 42 of the transformers 40A and 40B.

### Second Electrode Pad

As shown in FIGS. 5, 8, and 9, the second electrode pads 82 include the third pads 82A and the fourth pads 82C. As shown in FIGS. 8 and 9, the third pad 82A and the fourth pad 82C of the second electrode pads 82 are formed on the third upper surface 93s of the third insulator 93.

As shown in FIG. 5, the third pads 82A are disposed at the inner sides of the second coils 42 of the transformers 40A and 40B, as viewed in the z-direction. The fourth pads 82C are arranged at the outer sides of the transformers 40A and 40B, as viewed in the z-direction. The fourth pads 82C are arranged between the second coil 42 of the transformer 40A and the second coil 42 of the transformer 40B.

As shown in FIG. 8, the third pad 82A is each electrically connected by a via 55, which extends through the third insulation layer 932 of the third insulator 93, to the inner end wiring 52A, which is connected to the second coil 42. As shown in FIG. 9, the fourth pad 82C is each electrically connected by a via 56, which extends through the third insulation layer 932 of the third insulator 93, to the outer end wiring 52B, which is connected to the second coil 42. The vias 55 and 56 are formed from a material including one or more of Ti, TiN, Au, Ag, Cu, Al, and W.

As shown in FIG. 5, the second electrode pads 82 include the two third pads 82A and the two fourth pads 82C that are connected to the second coil 42 of the transformer 40A. Further, the second electrode pads 82 include the two third pads 82A and the two fourth pads 82C that are connected to the second coil 42 of the transformer 40B. The third pads 82A are arranged next to each other in the x-direction. The fourth pads 82C are arranged next to each other in the x-direction. The two fourth pads 82C are electrically connected to the second coil 42 of the transformer 40A and the second coil 42 of the transformer 40B. Thus, the two fourth pads 82C are shared by the second coil 42 of the transformer 40A and the second coil 42 of the transformer 40B.

As shown in FIGS. 8 and 9, the transformer chip 80 includes a fourth insulator 94 formed on the third upper surface 93s of the third insulator 93. In an example, the fourth insulator 94 includes a protective film 941 and a passivation film 942. The protective film 941 is formed on the third upper surface 93s of the third insulator 93. The protective film 941 protects the insulator 84 (third insulator 93). The protective film 941 is formed from, for example, a material including SiO₂. The passivation film 942 is formed on the protective film 941. The passivation film 942 is a surface-protection film of the transformer chip 80. The passivation film 942 is formed from, for example, a material including SiN. The fourth insulator 94 includes openings 94A, each exposing one of the second electrode pads 82 (third pad 82A, fourth pad 82C).

The transformer chip 80 further includes a resin layer 170 formed on the fourth insulator 94. The resin layer 170 is formed from, for example, a material containing polyimide (PI). The resin layer 170 is separated into an inner resin layer 171 and an outer resin layer 172 by an isolation trench 173. As shown in FIG. 5, the isolation trench 173 surrounds the transformers 40A and 40B in plan view. The resin layer 170 includes first resin open portions 174, which expose the first electrode pads 81, and second resin open portions 175, which expose the second electrode pads 82.

### Exposing Recess and Through Hole

As shown in FIGS. 7 to 9, the second insulator 92 includes exposing recesses 95 exposing the first electrode pads 81. Each exposing recess 95 is formed by sidewalls 92C of the second insulation layers 921 to 927 in the second insulator 92. The sidewalls 92C of the second insulation layers 921 to 927 face the first electrode pads 81. The sidewalls 92C of the second insulation layers 921 to 927 surround the first electrode pads 81, as viewed in the z-direction. Thus, the second insulator 92 includes through holes defined by the sidewalls 92C of the second insulation layers 921 to 927, which surround the first electrode pads 81. The through holes extend through the second insulator 92 in the z-direction. The sidewalls 92C of the second insulation layers 921 to 927 form an exposing recess wall 95C in each of the exposing recesses 95. The exposing recess wall 95C surrounds the corresponding first electrode pads 81, as viewed in the z-direction. Thus, the second insulator 92 of the first embodiment includes the through hole extending through the second insulator 92 from the second upper surface 92s to the second lower surface 92r. Further, the exposing recesses 95 of the first embodiment are the through holes extending through the second insulator 92 and exposing the first electrode pads 81.

The sidewalls 92C of the second insulation layers 921 to 927 in the second insulator 92 are formed such that the distance to the first electrode pad 81, as viewed in the z-direction, increases from the first upper surface 91s of the first insulator 91 toward the second upper surface 92s of the second insulator 92. Thus, the exposing recess wall 95C is stepped such that the distance to the first electrode pad 81 increases from the first upper surface 91s of the first insulator 91 toward the second upper surface 92s of the second insulator 92.

The sidewalls 92C of the second insulation layers 921 to 927 are formed so that the distance to the first electrode pad 81 increases from the first upper surface 91s of the first insulator 91 toward the second upper surface 92s of the second insulator 92. Thus, the exposing recess 95 has an opening width in the x-direction that increases from the first upper surface 91 toward the second upper surface 92s. Further, the exposing recesses 95 has an opening width in the y-direction that increases from the first upper surface 91 toward the second upper surface 92s.

As shown in FIGS. 8 and 9, the third insulator 93 includes through holes 96 exposing the first electrode pads 81. More specifically, the third insulation layers 931 and 932 forming the third insulator 93 each include a sidewall 93C facing the first electrode pad 81. The sidewalls 93C of the third insulation layers 931 and 932 surround the first electrode pad 81 in plan view.

Thus, the third insulator 93 includes the through holes 96 that extend through the third insulator 93 in the z-direction and are defined by the sidewalls 93C of the third insulation layers 931 and 932, which surround the first electrode pads 81. The through holes 96 of the third insulator 93 expose the first electrode pads 81.

The sidewalls 93C of the third insulation layers 931 and 932 in the third insulator 93 are formed such that the distance to the first electrode pad 81, as viewed in the z-direction, increases from the second upper surface 92s of the second insulator 92 toward the third upper surface 93s of the third insulator 93. The through holes 96 each include a through hole wall 96C formed by the sidewalls 93C of the third insulation layers 931 and 932. The through hole wall 96C is stepped such that the distance to the first electrode pad 81 increases from the third lower surface 93r toward the third upper surface 93s. The through hole wall 96C corresponds to a third wall.

The sidewall 93C of the third insulation layer 931, which is in contact with the second upper surface 92s of the second insulator 92, is located farther from the corresponding first electrode pads 81 than the sidewall 92C of the second insulation layer 927 in the second insulator 92 is. Thus, the third insulator 93 includes the through holes 96 extending through the third insulator 93 from the third upper surface 93s to the third lower surface 93r and connected to the corresponding exposing recesses 95 of the second insulator 92. Further, the through hole wall 96C of each through hole 96 is located farther from the corresponding first electrode pad 81 than the exposing recess wall 95C of the corresponding exposing recess 95 is as viewed in the z-direction.

As shown in FIGS. 8 and 9, the fourth insulator 94 includes through holes 97 exposing the first electrode pads 81. More specifically, the protective film 941 and the passivation film 942 of the fourth insulator 94 each include a sidewall 94C facing the corresponding first electrode pad 81. The sidewall 94C of the protective film 941 and the sidewall 94C of the passivation film 942 surround the first electrode pads 81 in plan view. The sidewalls 94C correspond to a fourth wall. Thus, the fourth insulator 94 includes the through holes 97 extending in the z-direction and defined by the sidewalls 94C of the protective film 941 and the passivation film 942.

The sidewall 94C of the protective film 941 and the sidewall 94C of the passivation film 942 are located at the same position in plan view. The sidewall 94C of the protective film 941 and the sidewall 94C of the passivation film 942 are formed to be farther from the first electrode pad 81 than the sidewall 93C of the uppermost third insulation layer 932 in the third insulator 93 is. Thus, the fourth insulator 94 includes the through holes 97 extending through the fourth insulator 94 and connected to the corresponding through holes 96 of the third insulator 93.

Further, the through holes 96 of the third insulator 93 are connected to the corresponding exposing recesses 95 of the second insulator 92. Thus, the through holes 97 of the fourth insulator 94 and the through holes 96 of the third insulator 93, together with the exposing recesses 95 of the second insulator 92, define exposing recesses that expose the first electrode pads 81. Further, as viewed in the z-direction, the sidewall 94C of the fourth insulator 94 is farther from the first electrode pad 81 than the through hole wall 96C of the through hole 96 in the third insulator 93.

As shown in FIGS. 5, 7, and 9, the transformer chip 80 includes the dummy patterns 150 disposed around the second coils 42 of the transformers 40A and 40B. The dummy patterns 150 may be omitted. As shown in FIGS. 8 and 9, the dummy patterns 150 are located on the second upper surface 92s of the second insulator 92 in the same manner as the second conductor 52. The dummy patterns 150 are embedded in the third insulator 93.

As shown in FIGS. 5 and 7, the dummy patterns 150 include a first dummy pattern 151, a second dummy pattern 152, and a third dummy pattern 153. The first dummy pattern 151, the second dummy pattern 152, and the third dummy pattern 153 are formed from a material including one or more of Ti, TiN, Au, Ag, Cu, Al, and W.

As shown in FIGS. 5 and 7, the first dummy pattern 151 is disposed in a region located between the second coil 42 of the transformer 40A and the second coil 42 of the transformer 40B in the x-direction in plan view. The first dummy pattern 151 has a pattern differing from that of the second coil 42. The first dummy pattern 151 is electrically connected to the outer end wiring 52B. The first dummy pattern 151 may be electrically connected to at least one of the two outer end wirings 52B. In this manner, the first dummy pattern 151 and the second coil 42 have the same potential. Thus, as the second reference potential at the second coil 42 varies, the voltage at the first dummy pattern 151 may become higher than that at the first coil 41 in the same manner as the second coil 42.

Although not shown in the drawings, the first dummy pattern 151 is located at the same position as the second coil 42 in the z-direction. Thus, the first dummy pattern 151 is located farther from the substrate 83 than the first coil 41 is. The dummy patterns 150 are disposed around those coils of the transformers 40A and 40B that are located near the chip main surface 80s of the transformer chip 80.

When the voltage at the first dummy pattern 151 is the same as that at the second coil 42, the voltage drop is limited between the second coil 42 and the first dummy pattern 151. This limits electric field concentration at the second coil 42.

As shown in FIGS. 5 and 7, the third dummy pattern 153 surrounds the second coils 42 of the transformers 40A and 40B. The third dummy pattern 153 is electrically connected to the first dummy pattern 151. Thus, as the second reference potential at the second coil 42 varies, the voltage at the third dummy pattern 153 may become higher than that at the first coil 41 in the same manner as the first dummy pattern 151.

As shown in FIG. 8, the third dummy pattern 153 is located at the same position as the second coil 42 in the z-direction. Although not shown in the drawings, the third dummy pattern 153 is located at the same position as the second coil 42 in the z-direction. Thus, the third dummy pattern 153 is located farther from the substrate 83 than the first coil 41 is. In this manner, the dummy patterns 151 to 153 are located at the same position in the z-direction.

When the voltage at the third dummy pattern 153 is the same as that at the second coil 42, the voltage drop is limited between the second coil 42 and the third dummy pattern 153. This limits electric field concentration at the second coil 42.

As shown in FIGS. 5 and 7, the second dummy pattern 152 surrounds the third dummy pattern 153 in plan view. The second dummy pattern 152 is independent from the second coil 42. That is, the second dummy pattern 152 is not electrically connected to the second coil 42.

As shown in FIGS. 8 and 9, the second dummy pattern 152 is located at the same position as the second coil 42 in the z-direction. Although not shown in the drawings, the second dummy pattern 152 is located at the same position as the second coil 42 in the z-direction. Thus, the second dummy pattern 152 is located farther from the substrate 83 than the first coil 41 is. The second dummy pattern 152 limits increases in the electric field intensity around the second coil 42 and limits electric field concentration at the second electrode pads 82 (third pads 82A, fourth pads 82C).

### Method for Manufacturing Transformer Chip

A method for manufacturing the transformer chip 80, which is shown in FIGS. 5 to 9, will now be described.

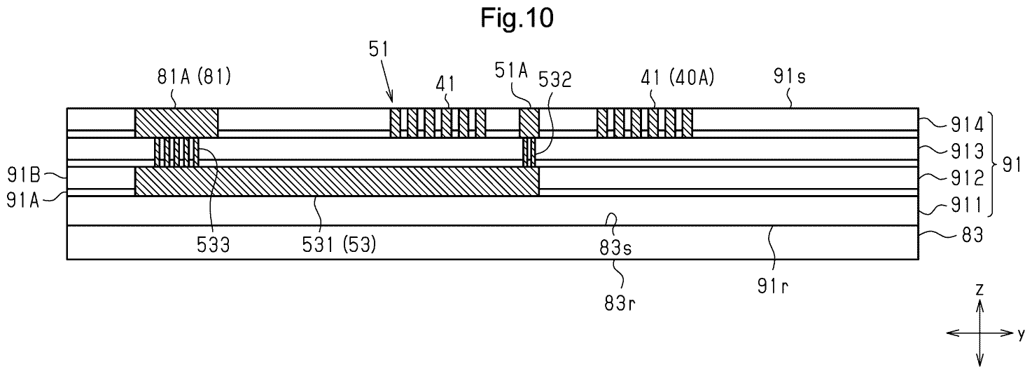

FIGS. 10 to 21 are schematic cross-sectional views illustrating exemplary manufacturing steps of the transformer chip 80. The cross-sectional structures illustrated in FIGS. 10 to 21 correspond to the cross-sectional structure of the transformer chip 80 shown in FIG. 8. Thus, the reference characters in FIGS. 10 to 21 correspond to the reference characters in FIG. 8. In FIGS. 10 to 21, to aid understanding, members including or corresponding to the final elements of the transformer chip 80 are indicated by the reference characters used in FIGS. 5 to 9 and shown in parenthesis.

As shown in FIG. 10, the method for manufacturing the transformer chip 80 includes forming the first insulator 91 on the substrate upper surface 83s of the substrate 83.

In an example, referring to FIG. 10, the first insulation layers 911 of the first insulator 91 are formed on the substrate 83 through chemical vapor deposition (CVD). The first insulation film 91A and the second insulation film 91B are repeatedly stacked to form the first insulation layers 912 to 914.

The method for manufacturing the transformer chip further includes forming the first conductor 51 and the inner interconnection 53. After forming the first insulation layer 912, through holes are selectively formed in the first insulation layer 912 through, for example, etching, and are filled with conductive material to form the inner interconnection 53. After forming the first insulation layer 913, through holes are selectively formed in the first insulation layer 913 through, for example, etching, and are filled with conductive material to form the vias 532 and 533. After forming the first insulation layer 914, through holes are selectively formed in the first insulation layer 914 through, for example, etching, and are filled with conductive material to form the first conductor 51. The first conductor 51 includes the first electrode pad 81 and the first coil 41 electrically connected to the first electrode pad 81 by the inner interconnection 53.

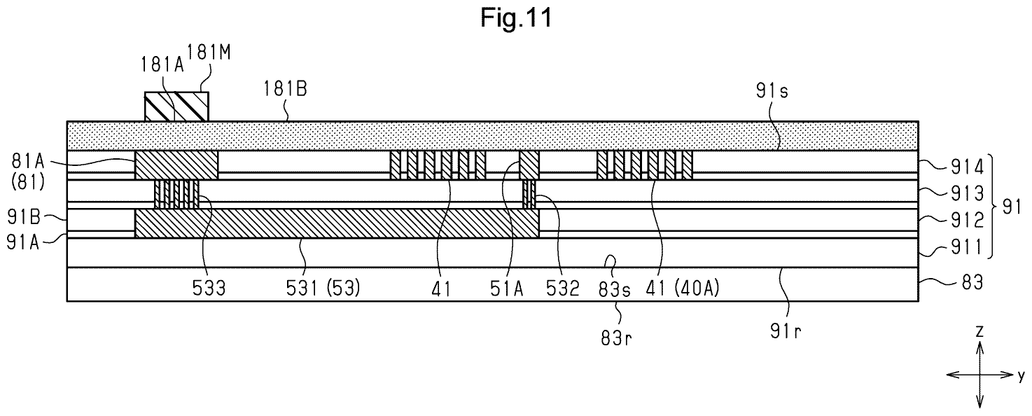

As shown in FIGS. 11 to 18, the method for manufacturing the transformer chip 80 further includes forming second insulator formation layers 181 to 187. The number of the second insulator formation layers 181 to 187 correspond to the number of the second insulation layers 921 to 927 in the second insulator 92.

As shown in FIGS. 11 to 15, the second insulator formation layers 181 to 187 are formed covering the first upper surface 91s of the first insulator 91.

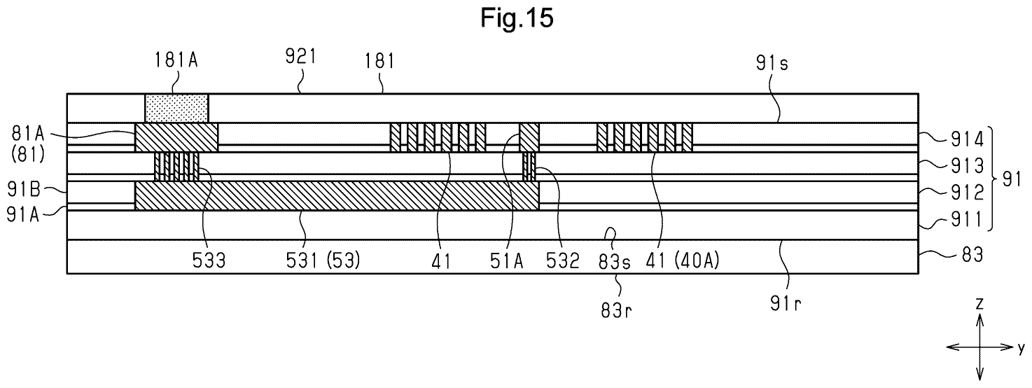

As shown in FIG. 15, the second insulator formation layers 181 to 187 include first sacrificial layers 181A to 187A and the second insulation layers 921 to 927, respectively.

As shown in FIGS. 11 to 13, the first sacrificial layer 181A is formed first. The formation of the first sacrificial layer 181A includes forming a first sacrificial film 181B and selectively removing the first sacrificial film 181B.

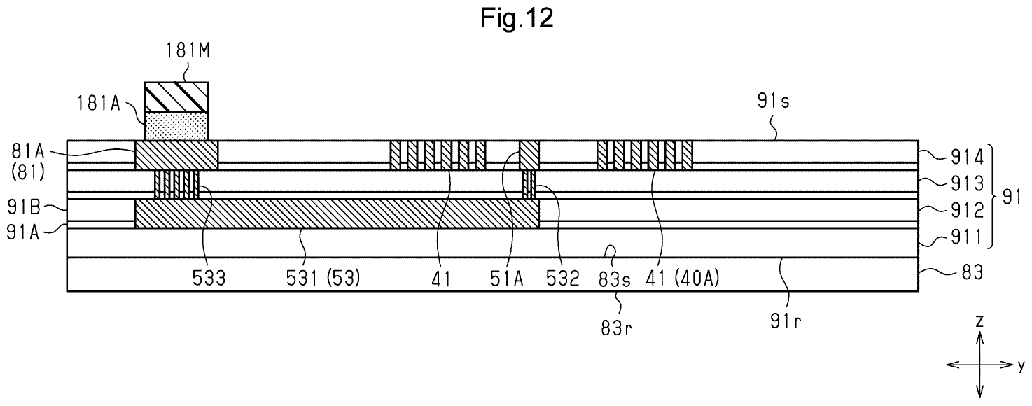

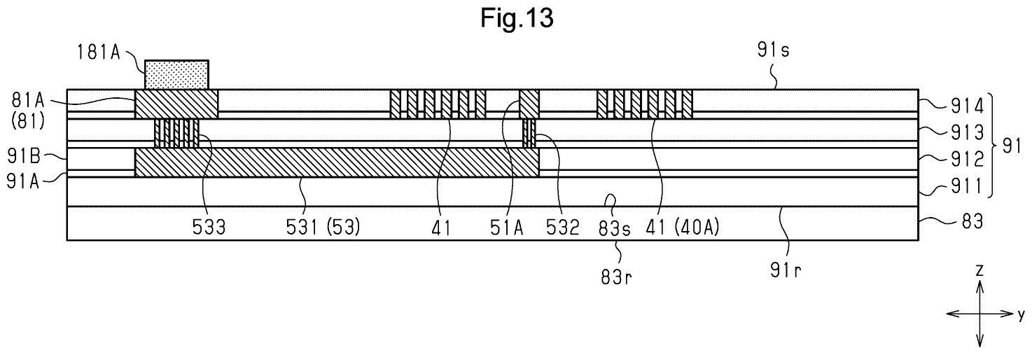

As shown in FIG. 11, the first sacrificial film 181B is formed covering the first upper surface 91s of the first insulator 91. The first sacrificial film 181B is, for example, an amorphous carbon film, and is formed through, for example, a CVD process. A mask 181M is then formed on the first sacrificial film 181B. The mask 181M covers a part of the first electrode pad 81, as viewed in the z-direction. The mask 181M is, for example, a resin film, and is formed through, for example, photolithography. As shown in FIG. 12, the mask 181M is used to selectively remove the first sacrificial film 181B and form the first sacrificial layer 181A. The first sacrificial film 181B may be removed through, for example, etching (e.g., dry etching). The mask 181M is then removed, thereby leaving the first sacrificial layer 181A shown in FIG. 13.

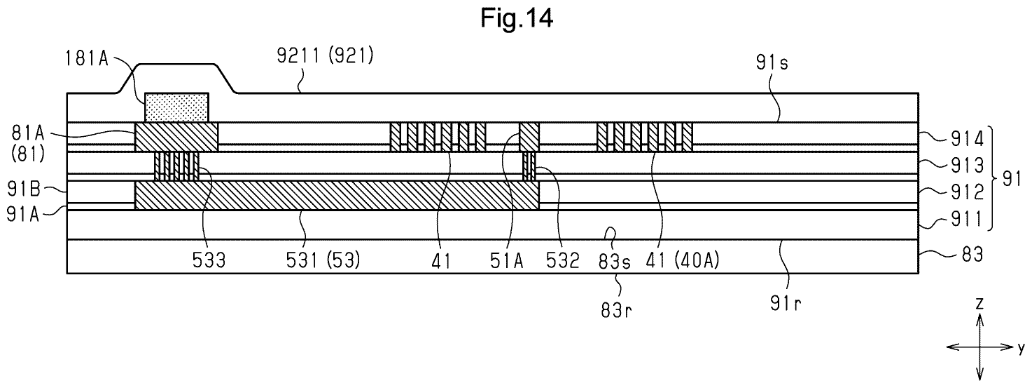

Then, as shown in FIGS. 14 and 15, the second insulation layer 921 is formed. As shown in FIG. 14, an insulation film 9211 is formed covering the first upper surface 91s of the first insulator 91 and the first sacrificial layer 181A through, for example, a CVD process. For example, the insulation film 9211 is flattened to remove the insulation film 9211 from the first sacrificial layer 181A and form the second insulation layer 921 shown in FIG. 15. The insulation film 9211 may be flattened through, for example, isotropic dry etching or chemical mechanical polishing (CMP). In this manner, the second insulator formation layer 181, which is the first one of second insulator formation layers, is formed.

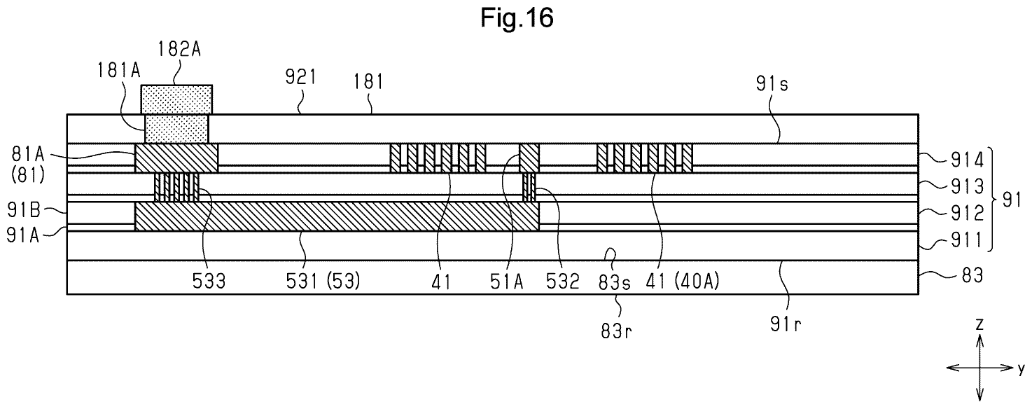

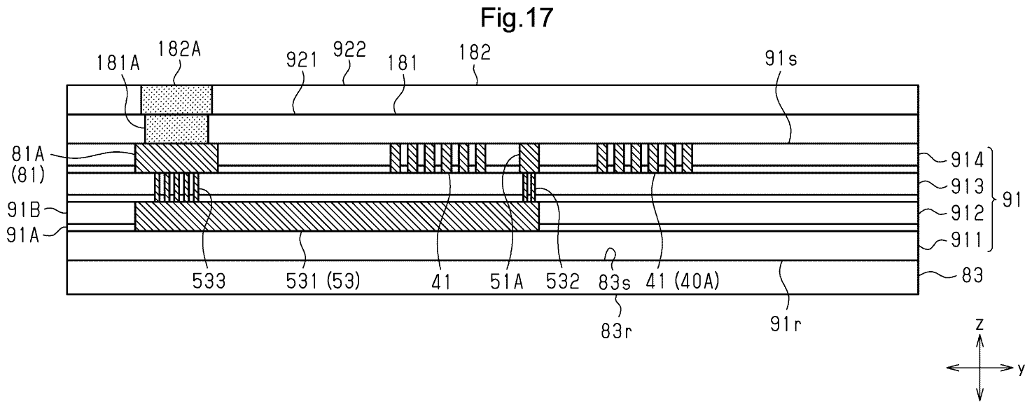

As shown in FIGS. 16 and 17, the second insulator formation layer 182, which is the second one of the second insulator formation layers, is formed. The second insulator formation layer 182 includes a first sacrificial film 182A and the second insulation layer 922.

As shown in FIG. 16, the first sacrificial film 182A, which is in the second one of the second insulator formation layers, covers the entire upper surface of the first sacrificial film 181A, which is in the underlying first one of the second insulator formation layers, and covers a part of the second insulation layer 921 surrounding the first sacrificial film 181A, which is in the first one of one of the second insulator formation layers. As long as the first sacrificial film 182A, which is the second one of the second insulator formation layers, covers the entire upper surface of the first sacrificial film 181A, which is the underlying first one of the second insulator formation layers, part of the sidewall of the first sacrificial film 182A may be aligned in the z-direction with part of the sidewall of the first sacrificial layer 181A, which is the underlayer.

As shown in FIG. 17, the second insulation layer 922, which is in the second one of the second insulator formation layers, is formed. The second insulation layer 922 is formed in the same manner as the second insulation layer 921, which is in the first one of the second insulator formation layers. This forms the second insulator formation layer 182, which is the second one of the second insulator formation layers and includes the first sacrificial film 182A and the second insulation layer 922.

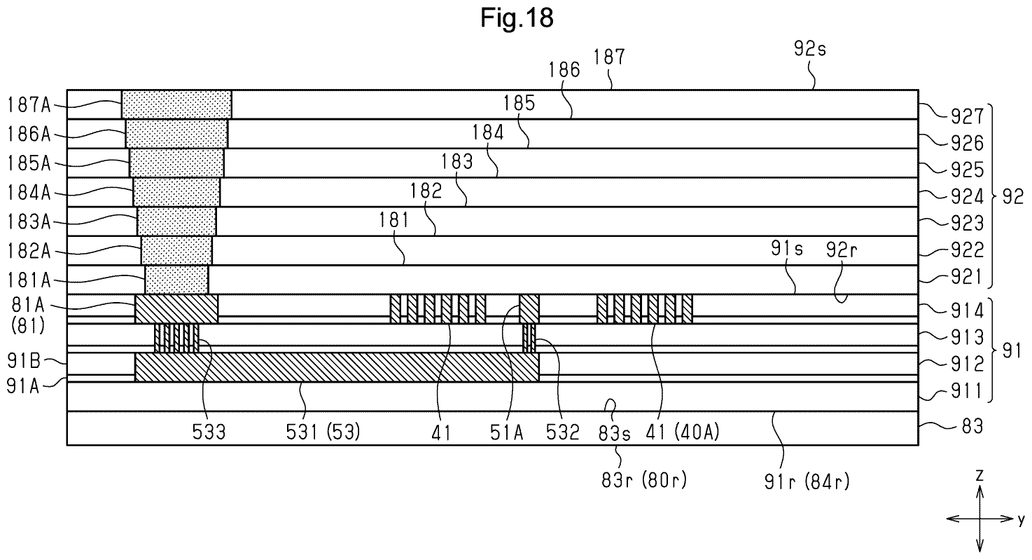

As shown in FIG. 18, the same process as that for forming the second insulator formation layers 181 and 182, which are the first and second one of the second insulator formation layers, is repeated to form the second insulator formation layers 181 to 187. The second insulator formation layers 181 to 187 include the first sacrificial layers 181A to 187A and the second insulation layers 921 to 927, respectively. FIG. 18 shows seven second insulator formation layers 181 to 187. However, there may be any number of second insulator formation layers.

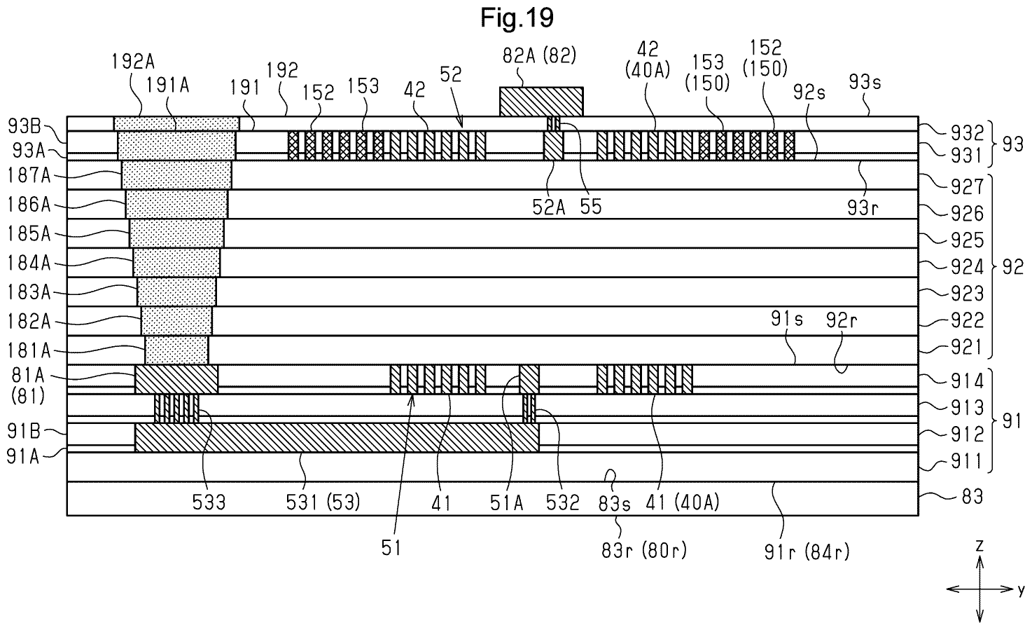

As shown in FIG. 19, the method for manufacturing the transformer chip 80 further includes forming the third insulator 93. The third insulator 93 of the first embodiment includes two third insulator formation layers 191 and 192. The third insulator 93 may be formed as long as there is at least one third insulator formation layer.

The third insulator formation layers 191 and 192 include second sacrificial layers 191A and 192A and the third insulation layers 931 and 932, respectively. The second sacrificial layers 191A and 192A may be formed in the same manner as the first sacrificial layers 181A to 187A included in the second insulator formation layers 181 to 187. In the same manner as the first insulation layers 912 to 914 of the first insulator 91, for example, a CVD process is performed to form the third insulation layer 931 by stacking the first insulation film 93A and the second insulation film 93B. The third insulation layer 931 is formed by stacking only the second insulation film 93B.

The method for manufacturing the transformer chip 80 further includes forming the second conductor 52. After forming the third insulator formation layer 191, through holes are selectively formed in the third insulation layer 931 through, for example, etching, and are filled with conductive material to form the second conductor 52. The second conductor 52 includes the second coil 42, the inner end wiring 52A, and the outer end wiring 52B. When forming the second conductor 52, the dummy patterns 150 are formed in the same manner as the second conductor 52.

The method for manufacturing the transformer chip 80 further includes forming the vias 55 and 56. After forming the third insulator formation layer 192, through holes are selectively formed in the third insulation layer 932 through, for example, etching, and are filled with conductive material to form the via 55, which is electrically connected to the inner end wiring 52A. Although not shown in the drawings, the via 56 (refer to FIG. 9), which is electrically connected to the outer end wiring 52B, is also formed.

The method for manufacturing the transformer chip 80 further includes forming the second electrode pad 82. The second electrode pad 82 is formed on the upper surface of the third insulation layer 932 of the uppermost third insulator formation layer 192. The second electrode pad 82 is formed through, for example, a CVD process.

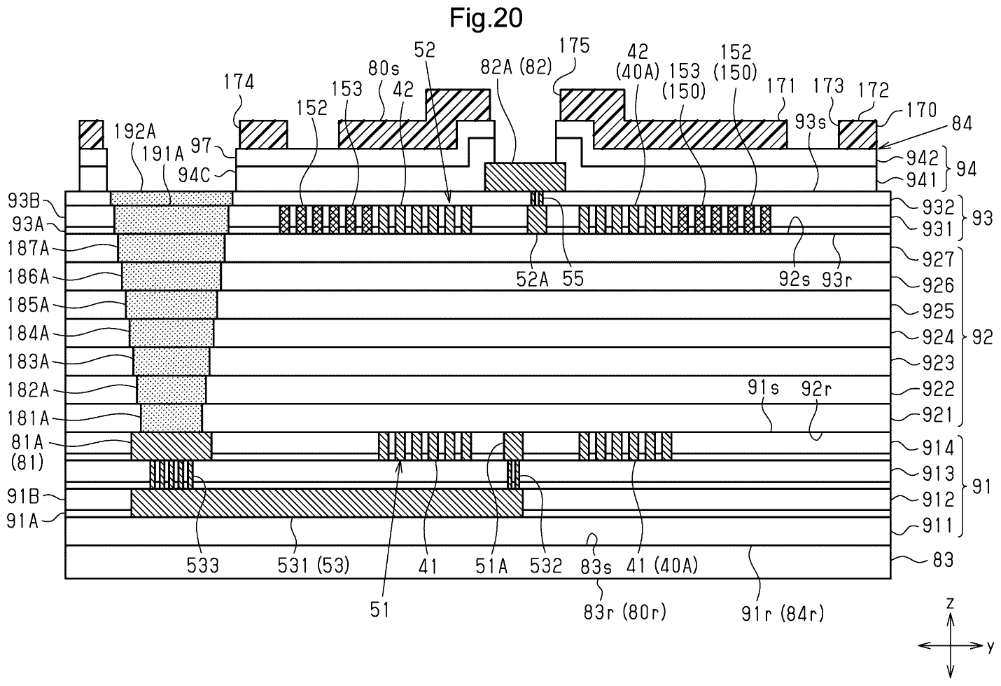

As shown in FIG. 20, the method for manufacturing the transformer chip 80 further includes forming the fourth insulator 94. The fourth insulator 94 includes the protective film 941 and the passivation film 942. The protective film 941 and the passivation film 942 are formed through, for example, a CVD process.

The method for manufacturing the transformer chip 80 further includes forming the resin layer 170. The resin layer 170 is formed through, for example, a photolithography process.

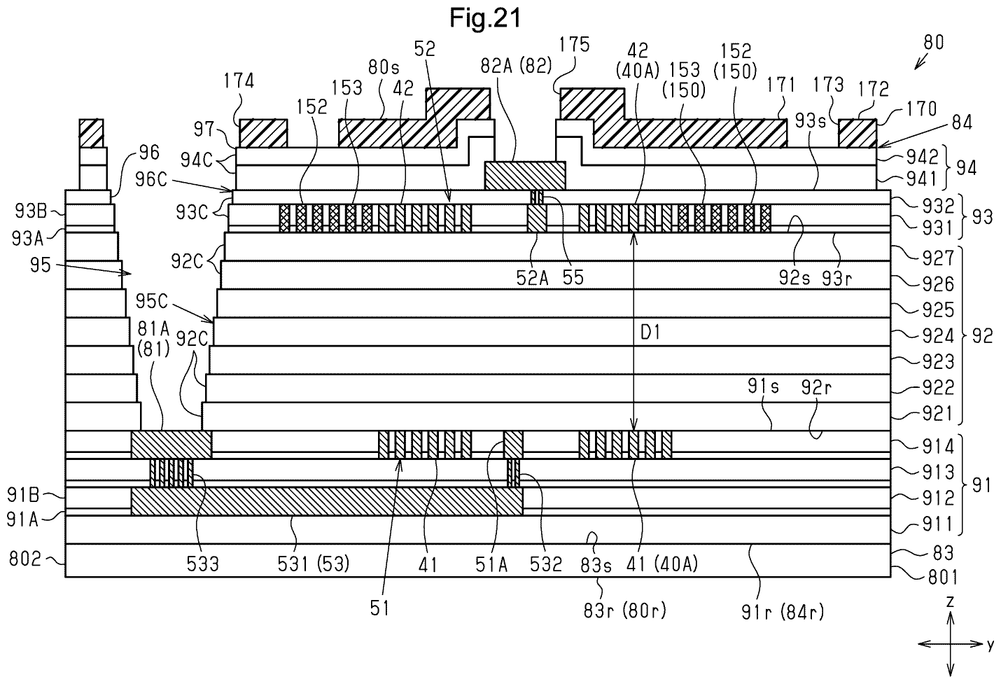

The method for manufacturing the transformer chip 80 further includes forming the through hole 97 in the fourth insulator 94. The through hole 97 of the fourth insulator 94 is formed by, for example, etching the passivation film 942 and the protective film 941. As shown in FIG. 21, the method for manufacturing the transformer chip 80 further includes forming the through holes 96 of the third insulator 93 and the exposing recesses 95 of the second insulator 92. The through hole 96 of the third insulator 93 is formed by collectively removing the second sacrificial layers 191A and 192A. The exposing recesses 95 of the second insulator 92 is formed by collectively removing the first sacrificial layers 181A to 187A. The first sacrificial layers 181A to 187A and the second sacrificial layers 191A and 192A are formed from amorphous carbon. The amorphous carbon may be performed through oxygen ashing (O2 ashing). In this manner, the second sacrificial layers 191A and 192A and the first sacrificial layers 181A to 187A are collectively removed to form the through holes 96 of the third insulator 93 and the exposing recesses 95 of the second insulator 92.

### Operation

The first coil 41 and the second coil 42 are located at opposite sides of the second insulator 92. The first coil 41 and the second coil 42 are spaced apart from each other by distance D1, which is determined by the thickness of the second insulator 92. The dielectric breakdown voltage of the transformer chip 80 is primarily determined by the distance D1 between the first coil 41 and the second coil 42. Accordingly, in the transformer chip 80, the dielectric breakdown voltage of the transformer chip 80 can be set by the thickness of the second insulator 92. Thus, the thickness of the second insulator 92 can be increased to increase the dielectric breakdown voltage of the transformer chip 80.

The exposing recess wall 95C of the exposing recess 95 is stepped such that the distance to the first electrode pad 81 increases from the first upper surface 91s of the first insulator 91 to the second upper surface 92s of the second insulator 92 on the first insulator 91. This limits interference of a capillary, which connects the wire W2 to the first electrode pad 81, with the second insulator 92.

As viewed in the z-direction, the through hole wall 96C of the through hole 96 in the third insulator 93 is farther from the first electrode pad 81 than the exposing recess wall 95C of the exposing recesses 95 is. This limits interference of the capillary, which connects the wire W2 to the first electrode pad 81, with the third insulator 93.

As viewed in the z-direction, the sidewall 94C of the fourth insulator 94 is farther from the first electrode pad 81 than the through hole wall 96C of the through hole 96 in the third insulator 93 is. This limits interference of the capillary, which connects the wire W2 to the first electrode pad 81, with the fourth insulator 94.

A transformer chip of a comparative example will now be described. The transformer chip of the comparative example has a structure in which the exposing recess 95 of the second insulator 92, the through hole 96 of the third insulator 93, and the through hole 97 of the fourth insulator 94 are omitted from the transformer chip 80 of the first embodiment. Further, in the transformer chip of the comparative example, the first electrode pad 81 is formed on the third upper surface 93s of the third insulator 93 in the same manner as the second electrode pad 82, and electrically connected to the first coil 41 by an interconnection, which extends through the third insulator 93 and the second insulator 92, and the inner interconnection 53. The transformer chip of the comparative example will be described using the same reference characters as the corresponding members in the transformer chip 80 of the first embodiment.

In the transformer chip of the comparative example, the interconnection extending through the second insulator 92 and the third insulator 93 is formed by a via or the like. Thus, in the transformer chip of the comparative example, when forming the second insulator 92 and the third insulator 93, in addition to forming the second insulation layers 921 to 927 and the third insulation layers 931 and 932, the vias or the like for the interconnections also have to be formed. Accordingly, in the method for manufacturing the transformer chip of the comparative example, the formation of the second insulation layers 921 to 927, the formation of the through holes in the second insulation layers 921 to 927, and the formation of the vias or the like in through holes are alternately performed.

In this regard, the first electrode pads 81 in the transformer chip 80 of the first embodiment are embedded in the first insulator 91 and exposed from the first upper surface 91s of the first insulator 91. Thus, the transformer chip 80 of the first embodiment may be formed by repeating only the process for forming the second insulation layers 921 to 927. This reduces the time for manufacturing the transformer chip 80 of the first embodiment.

Further, in the transformer chip of the comparative example that does not include the exposing recesses 95, the second insulation layers 921 to 927 of the second insulator 92 are formed to cover the entire first upper surface 91s of the first insulator 91 in plan view. The second insulation layers 921 to 927 formed by a material including SiO₂ produces compressive stress. Thus, when the second insulator 92 has a large thickness, that is, when the second insulation layers 921 to 927 are increased in number, significant warpage occurs in the substrate 83.

In this regard, in the transformer chip 80 of the first embodiment, the second insulator 92 is formed by stacking the second insulator formation layers 181 to 187, which include the first sacrificial layers 181A to 187A and the second insulation layers 921 to 927, and collectively removing the first sacrificial layers 181A to 187A. The formation of the first sacrificial layers 181A to 187A reduces the stress on the second insulation layers 921 to 927. This limits warpage of the substrate 83. Limited warpage allows the thickness of the second insulator 92 to be increased. Thus, the distance between the first coil 41 and the second coil 42 can be increased, and the dielectric breakdown voltage of the transformer chip 80 can be increased.

The first electrode pad 81 is embedded in the first insulator 91 and exposed from the first upper surface 91s of the first insulator 91. The second insulator 92 and the third insulator 93 are disposed on the first insulator 91, and the second electrode pad 82 is disposed on the third upper surface 93s of the third insulator 93. Thus, in comparison with the transformer chip of the comparative example in which the first electrode pads 81 and the second electrode pads 82 are arranged at the same position in the z-direction, the distance between the second electrode pads 82 and the first electrode pads 81 can be increased in the transformer chip 80 of the first embodiment.

### Advantages

The first embodiment has the advantages described below.

(1-1) The transformer chip 80 includes the substrate 83, the first insulator 91, the first conductor 51, the second insulator 92, and the second conductor 52. The substrate 83 includes the substrate upper surface 83s. The first insulator 91 is formed on the substrate upper surface 83s and includes the first upper surface 91s facing the same direction as the substrate upper surface 83s. The first conductor 51 is embedded in the first insulator 91 and exposed from the first upper surface 91s. The second insulator 92 covers the first upper surface 91s and the first conductor 51 and includes the second upper surface 92s facing the same direction as the first upper surface 91s. The second conductor 52 is disposed on the second upper surface 92s.

The first conductor 51 includes the first coil 41 and the first electrode pad 81, which is electrically connected to the first coil 41. The second conductor 52 includes the second coil 42 facing the first coil 41 in the z-direction, which is perpendicular to the first upper surface 91s. The second insulator 92 includes the second insulation layers 921 to 927 disposed on the first upper surface 91s in the z-direction, and the exposing recess 95, which extends through the second insulation layers 921 to 927 and exposes the first electrode pad 81. The exposing recesses 95 includes the exposing recess wall 95C, which is formed by the sidewalls 92 of the second insulation layers 921 to 927. The exposing recess wall 95C is stepped such that the distance to the first electrode pad 81 increases from the first upper surface 91s toward the second upper surface 92s.

The first coil 41 and the second coil 42 are located at opposite sides of the second insulator 92. The distance D1 between the first coil 41 and the second coil 42 is determined by the thickness of the second insulator 92. The dielectric breakdown voltage of the transformer chip 80 is primarily determined by the distance D1 between the first coil 41 and the second coil 42. Accordingly, in the transformer chip 80, the dielectric breakdown voltage of the transformer chip 80 can be set by the thickness of the second insulator 92. Thus, the thickness of the second insulator 92 can be increased to increase the dielectric breakdown voltage of the transformer chip 80.

(1-2) The exposing recess wall 95C of the exposing recess 95 is stepped such that the distance to the first electrode pad 81 increases from the first upper surface 91s of the first insulator 91 to the second upper surface 92s of the second insulator 92 on the first insulator 91. This limits interference of a capillary, which connects the wire W2 to the first electrode pad 81, with the second insulator 92.

(1-3) The first electrode pads 81 are embedded in the first insulator 91 and exposed from the first upper surface 91s of the first insulator 91. Thus, the transformer chip 80 of the first embodiment may be formed by repeating only the step for forming the second insulation layers 921 to 927. This reduces the time for manufacturing the transformer chip 80 of the first embodiment.

(1-4) In the transformer chip 80 of the first embodiment, the second insulator 92 is formed by stacking the second insulator formation layers 181 to 187, which include the first sacrificial layers 181A to 187A and the second insulation layers 921 to 927, and collectively removing the first sacrificial layers 181A to 187A. The formation of the first sacrificial layers 181A to 187A reduces the stress on the second insulation layers 921 to 927. This limits warpage of the substrate 83. Limited warpage allows the thickness of the second insulator 92 to be increased. Thus, the distance between the first coil 41 and the second coil 42 can be increased, and the dielectric breakdown voltage of the transformer chip 80 can be increased.

(1-5) The first electrode pad 81 is embedded in the first insulator 91 and exposed from the first upper surface 91s of the first insulator 91. The second insulator 92 and the third insulator 93 are disposed on the first insulator 91, and the second electrode pad 82 is disposed on the third upper surface 93s of the third insulator 93. Thus, in comparison with the transformer chip in which the first electrode pad 81 and the second electrode pad 82 are arranged at the same position in the z-direction, the distance between the second electrode pad 82 and the first electrode pad 81 can be increased in the transformer chip 80 of the first embodiment.

### Modified Example of First Embodiment

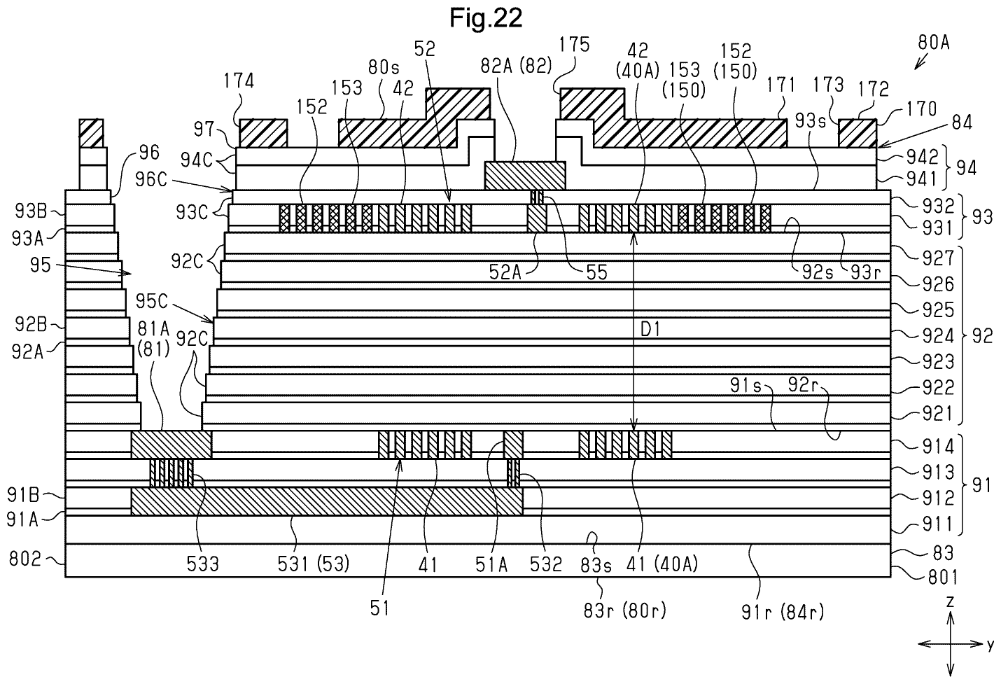

FIG. 22 shows a transformer chip 80A in which the second insulator 92 is formed by stacking the second insulation layers 921 to 927, each including a first insulation film 92A and a second insulation film 92B. The first insulation film 92A is formed from a material including SiN, SiC, SiCN, or the like. The second insulation film 92B is formed from a material including SiO₂.

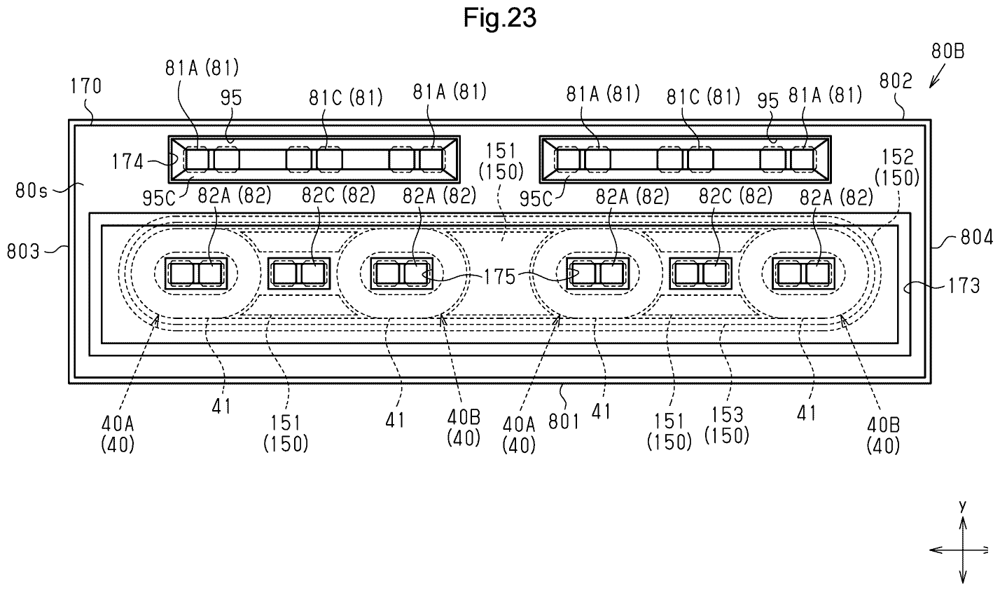

FIG. 23 shows a transformer chip 80B including exposing recesses 95 configured to expose the first electrode pads 81 connected to the transformer 40A and the first electrode pads 81 connected to the transformer 40B. A transformer chip may be configured so that a single exposing recess 95 exposes all of the first electrode pads 81.

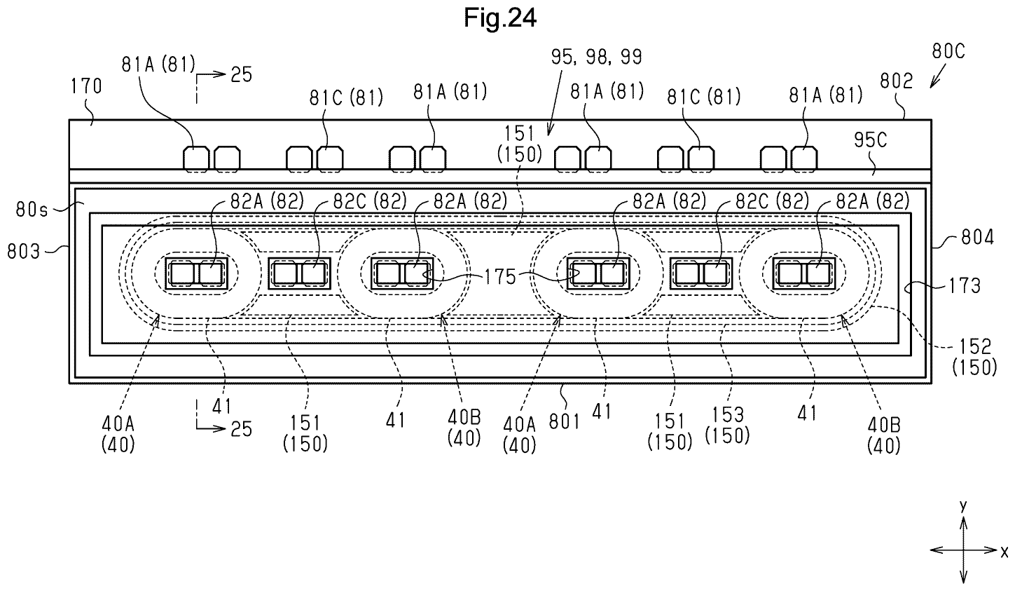

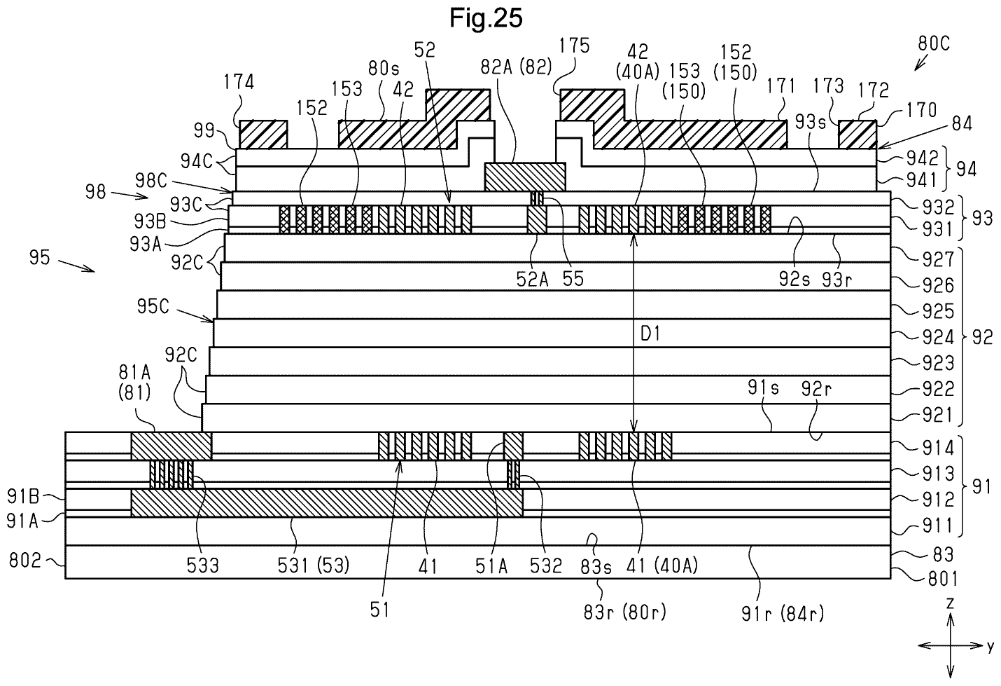

FIGS. 24 and 25 show a transformer chip 80C that includes the second insulator 92 and the third insulator 93.

The exposing recess wall 95C of the second insulator 92 is located between the first electrode pad 81 and the first and second coils 41 and 42, in plan view. As shown in FIG. 24, the exposing recess wall 95C extends in the x-direction. As shown in FIG. 25, the exposing recess wall 95C faces the same direction as the chip side surface 802. The second insulator 92 is not formed between the chip side surface 802 and the first electrode pad 81, in plan view. Thus, the exposing recess 95 of the second insulator 92 includes an open side, and the exposing recess wall 95C and the open side are located at opposite sides of the first electrode pad 81.

The third insulation layers 931 and 932 of the third insulator 93 each include the sidewall 93C facing the first electrode pad 81. The sidewalls 93C of the third insulation layers 931 and 932 extend in the x-direction, in plan view, in the same manner as the exposing recess wall 95C of the second insulator 92. Thus, the third insulator 93 includes an exposing recess wall 98C defined by the sidewalls 93C. The third insulator 93 includes an exposing recess 98 having an open side, and the exposing recess wall 98C and the open side are located at opposite sides of the first electrode pad 81. The fourth insulator 94 has an exposing recess 99 including the sidewall 94C in the same manner as the third insulator 93.

The transformer chip 80C has the same advantages as the transformer chip 80 of the first embodiment. Further, in the transformer chip 80C, the second insulator 92 is not formed between the first electrode pad 81 and the chip side surface 802. This allows a wire connected to the first electrode pad 81 to extend from the exposing recesses 95 of the second insulator 92 in a sideward direction (y-direction in FIG. 25). Thus, the height of the wire connected to the first electrode pad 81 in the z-direction can be shortened, and the distance to a wire connected to the second electrode pad 82 can be increased.

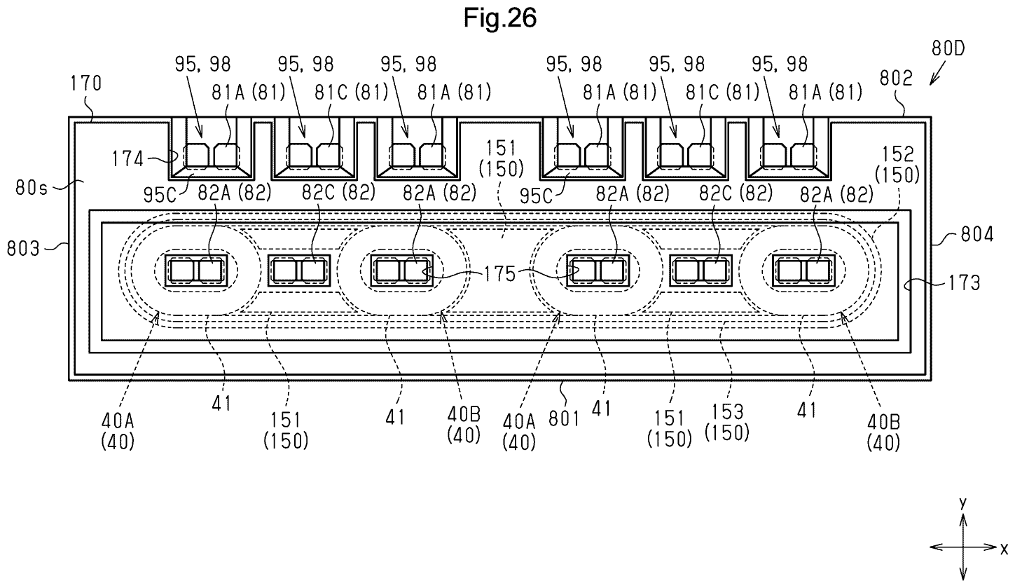

FIG. 26 shows a transformer chip 80D including exposing recesses 95 and 98 formed for each first electrode pad 81.

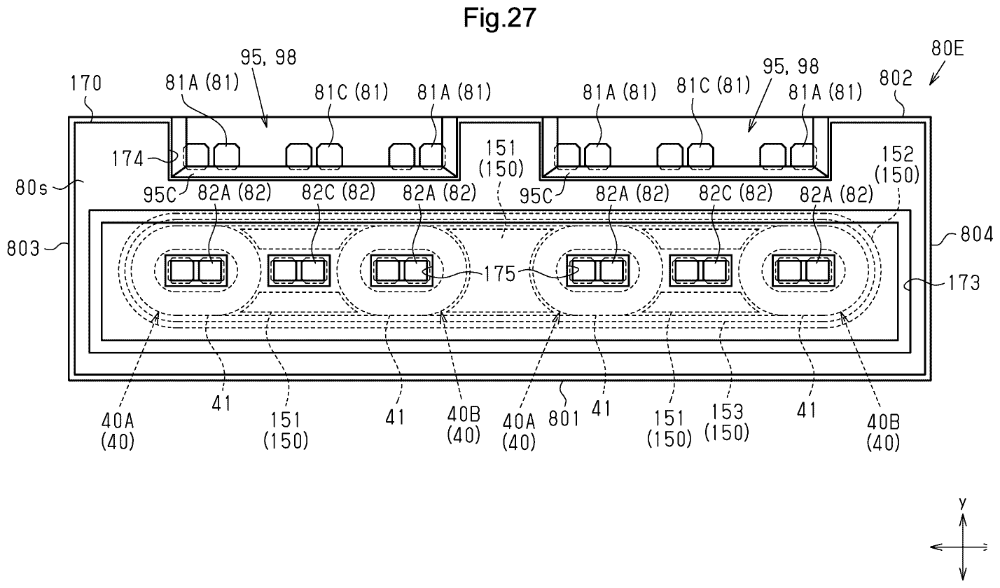

FIG. 27 shows a transformer chip 80E in which the exposing recesses 95 and 98 are integrated into a single exposing recess 95 configured to expose the first electrode pads 81, which are connected to the transformer 40A, and the first electrode pads 81, which are connected to the transformer 40B.

The through holes 96 of the third insulator 93 may be formed without using the second sacrificial layers 191A and 192A. For example, the through holes 96 of the third insulator 93 are formed by etching the third insulation layers 932 and 931 exposed from the through holes 97 of the fourth insulator 94. Further, the exposing recesses 95 may be formed by collectively removing the first sacrificial layers 181A to 187A from the through holes 96 of the third insulator 93.

The sidewall 93C of the third insulator 93 may be located at the same position as the exposing recess wall 95C of the exposing recess 95, as viewed in the z-direction.

The sidewall 94C of the fourth insulator 94 may be located at the same position as the sidewall 93C of the through holes 96 in the third insulator 93, as viewed in the z-direction.

### Second Embodiment

### Overview of Signal Transmission Device

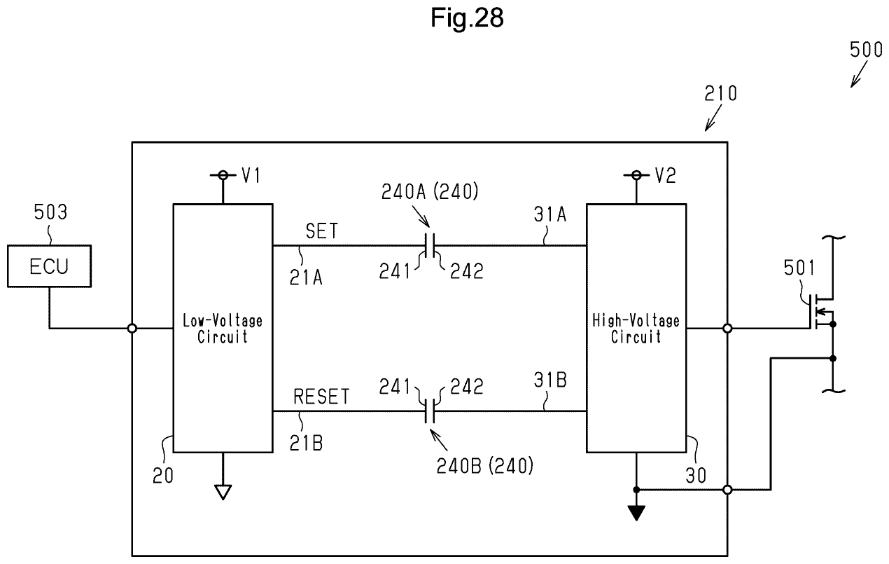

With reference to FIGS. 28 to 30, the configuration of a signal transmission device 210 in accordance with a second embodiment will now be described.

The signal transmission device 210 in accordance with the second embodiment differs from the signal transmission device 10 of the first embodiment in that a capacitor chip 280 includes a capacitor 240. The description hereafter will focus on the differences from the signal transmission device 10 of the first embodiment. The same reference characters are given to those components that are the same as the corresponding components in the signal transmission device 10 of the first embodiment. Such components will not be described in detail.

FIG. 28 illustrates one example of the circuit configuration of the signal transmission device 210 in a simplified manner. The signal transmission device 210 includes the capacitor 240 located between the low-voltage circuit 20 and the high-voltage circuit 30. That is, the low-voltage circuit 20 and the high-voltage circuit 30 are connected by the capacitor 240. The signal transmission device 210 is configured to transmit signals from the low-voltage circuit 20 to the high-voltage circuit 30 via the capacitor 240.

The signal transmission device 210 includes two capacitors 240 corresponding to the two signals (set signal and reset signal) transmitted from the low-voltage circuit 20 to the high-voltage circuit 30. In an example, the capacitor 240 used for the transmission of the set signal is referred to as the first capacitor 240A, and the capacitor 240 used for the transmission of the reset signal is referred to as the second capacitor 240B.

The first capacitor 240A includes a first electrode plate 241 and a second electrode plate 242. The first electrode plate 241 of the first capacitor 240A is electrically connected by the low-voltage signal line 21A to the low-voltage circuit 20. The second electrode plate 242 of the first capacitor 240A is electrically connected by the high-voltage signal line 31A to the high-voltage circuit 30.

The second capacitor 240B includes a first electrode plate 241 and a second electrode plate 242. The first electrode plate 241 of the second capacitor 240B is electrically connected by the low-voltage signal line 21B to the low-voltage circuit 20. The second electrode plate 242 of the second capacitor 240B is electrically connected by the high-voltage signal line 31B to the high-voltage circuit 30.

### Capacitor Chip

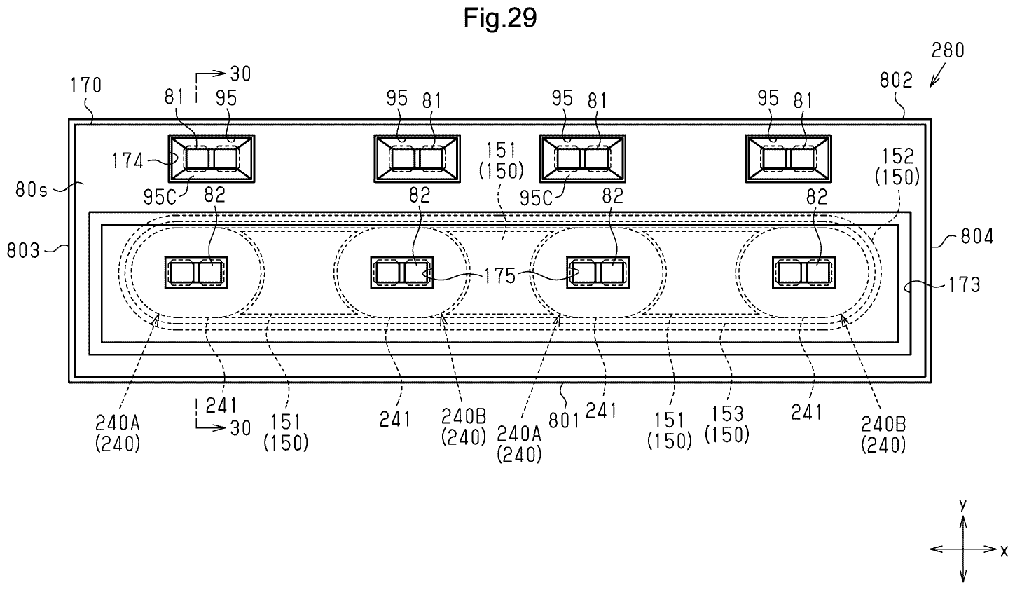

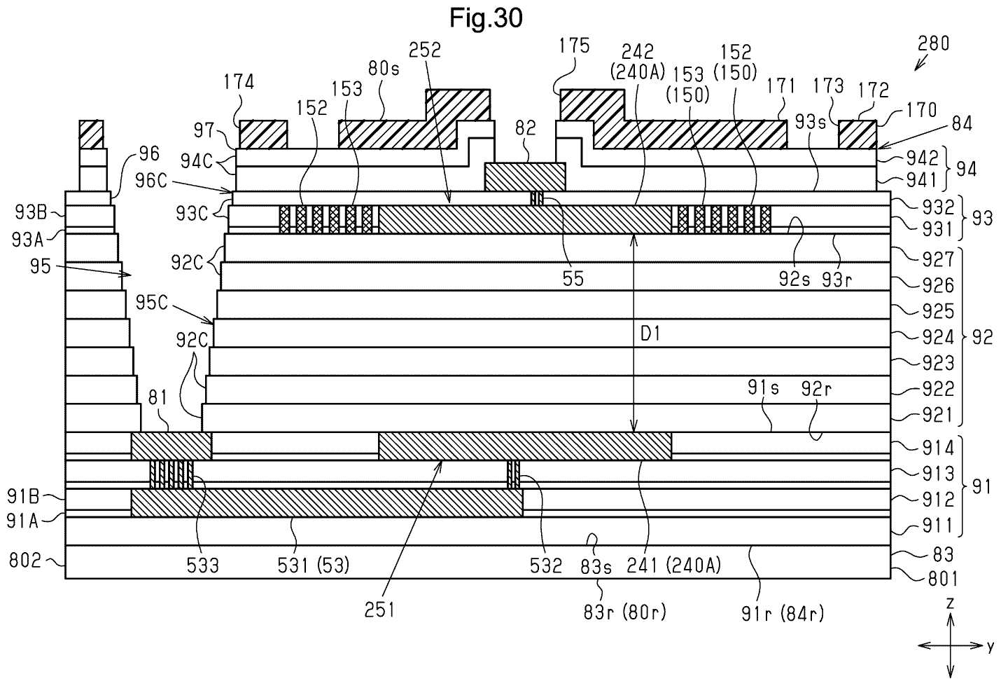

FIG. 29 is a schematic plan view of the capacitor chip 280. In FIG. 29, the capacitor 240 (240A, 240B), the first electrode pads 81, the second electrode pads 82, and the dummy patterns 150 are depicted in broken lines for clarity. FIG. 30 is a cross-sectional view of the capacitor chip 280 taken along line 30-30 in FIG. 29 and shows the insulator 84, the first electrode plate 241, the second electrode plate 242, the dummy pattern 150, the first electrode pad 81, and the second electrode pad 82.

The capacitor chip 280 shown in FIGS. 29 and 30 replaces the transformer chip 80 of the first embodiment. Accordingly, the signal transmission device 210 in accordance with the second embodiment includes the low-voltage circuit chip 60 and the high-voltage circuit chip 70, which are shown in FIG. 2, and the capacitor chip 280, which is shown in FIG. 29. The capacitor chip 280 is one example of an isolation chip.

As shown in FIGS. 29 and 30, the capacitor chip 280 includes four chip side surfaces 801, 802, 803, and 804 extending perpendicular to both the chip main surface 80s and the chip back surface 80r.

As shown in FIG. 30, the capacitor chip 280 includes the substrate 83 and the insulator 84.

The insulator 84 includes the first insulator 91, the second insulator 92, and the third insulator 93.

The capacitor chip 280 includes a first conductor 251 and a second conductor 252. The first conductor 251 is embedded in the first insulator 91. The second conductor 252 is embedded in the third insulator 93.

The first conductor 251 includes the first electrode pad 81 and the first electrode plate 241. In an example, the first electrode plate 241 is elliptical in plan view and elongated in the x-direction. The first electrode plate 241 may have any shape. The first electrode plate 241 is formed from a material including one or more of Ti, TiN, Au, Ag, Cu, Al, and W. The first electrode plate 241 is electrically connected by the inner interconnection 53 to the first electrode pads 81.

The second conductor 252 includes the second electrode plate 242. In an example, the second electrode plate 242 is elliptical in plan view and elongated in the x-direction. The second electrode plate 242 may have any shape. The second electrode plate 242 is formed from a material including one or more of Ti, TiN, Au, Ag, Cu, Al, and W.

### Advantages

The second embodiment has the advantages described below.

(2-1) The capacitor chip 280 of the second embodiment has the same advantages as the transformer chip 80 of the first embodiment.

(2-2) The capacitors 240A and 240B each include the first electrode plate 241 and the second electrode plate 242. The first electrode plate 241 is electrically connected by the low-voltage signal line 21A to the low-voltage circuit 20. The second electrode plate 242 is electrically connected by the high-voltage signal line 31A to the high-voltage circuit 30. Accordingly, the first electrode pads 81 and the second electrode pads 82 are less in number in the capacitor chip 280 than in the transformer chip 80. This decreases the number of wires in the signal transmission device 210, and facilitates the connection of the capacitor chip 280 to the low-voltage circuit 20 and the high-voltage circuit 30.

(2-3) The first electrode plate 241 and the second electrode plate 242 are located at opposite sides of the second insulator 92 in the z-direction. The capacitance of the capacitors 240A and 240B can be readily set by the thickness of the second insulator 92, that is, the number of the second insulation layers in the second insulator 92.

### Modified Example of Second Embodiment

The first electrode plate 241 and the second electrode plate 242 may differ in size as viewed in the z-direction. Further, the first electrode plate 241 and the second electrode plate 242 may differ in shape as viewed in the z-direction.

The inner interconnection 53, which electrically connects the first electrode plate 241 and the first electrode pad 81, may be formed by the first insulation layer 914, in which the first electrode plate 241 is embedded, or the underlayer of the first insulation layer 914, in which the first electrode plate 241 is embedded.

### Modified Examples

The above embodiments may be modified as described below. The modified examples described below may be combined as long as there is no technical contradiction. In the modified examples described hereafter, same reference characters are given to those components that are the same as the corresponding components of the above embodiments. Such components will not be described in detail.

The resin layer 170 may be omitted.

The fourth insulator 94 may include a plurality of layers. For example, the protective film 941 may include a plurality of insulation films.

Any one of the transformer chips 80, and 80A to 80E and the capacitor chip 280 may be mounted on the high-voltage die pad 111 shown in FIG. 2. Further, any one of the transformer chips 80, and 80A to 80E and the capacitor chip 280 may be mounted on each of the low-voltage die pad 101 and the high-voltage die pad 111.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The z-direction referred to in this specification does not necessarily have to be the vertical direction and does not necessarily have to completely coincide with the vertical direction. Accordingly, in the structures disclosed above (e.g., structure shown in FIG. 1), upward and downward in the z-direction as referred to in this specification is not limited to upward and downward in the vertical direction. For example, the x-direction may be the vertical direction. Alternatively, the y-direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### Clause 1

An isolation chip, including:
a substrate (83) including a substrate upper surface (83s);
a first insulator (91) formed on the substrate upper surface (83s) and including a first upper surface (91s) facing the same direction as the substrate upper surface (83s);
a first conductor (51, 251) embedded in the first insulator (91) and exposed from the first upper surface (91s);
a second insulator (92) covering the first upper surface (91s) and the first conductor (51, 251) and including a second upper surface (92s) facing the same direction as the first upper surface (91s); and
a second conductor (52, 252) disposed on the second upper surface (92s), where
the first conductor (51, 251) includes a first main body (41, 241) and a first electrode pad (81) electrically connected to the first main body (41, 241),
the second conductor (52, 252) includes a second main body (42, 242) facing the first main body (41, 241) in a thickness direction that is perpendicular to the first upper surface (91s),
the second insulator (92) includes insulation layers (921-927) disposed on the first upper surface (91s) in the thickness direction, and an exposing recess (95) extending through the insulation layers (921-927) and exposing the first electrode pad (81),
the exposing recess (95) includes an exposing recess wall (95C) formed by sidewalls of the insulation layers, and
the exposing recess wall (95C) is stepped such that a distance to the first electrode pad (81) increases from the first upper surface (91s) toward the second upper surface (92s).

### Clause 2

The isolation chip according to clause 1, where
the exposing recess (95) is a through hole extending through the second insulator (92), and
the exposing recess wall (95C) surrounds the first electrode pad (81) as viewed in the thickness direction.

### Clause 3

The isolation chip according to clause 1 or 2, where the exposing recess (95) includes an open side, and the exposing recess wall (95C) and the open side are located at opposite sides of the first electrode pad (81).

### Clause 4

The isolation chip according to any one of clauses 1 to 3, where the first main body (41) and the second main body (42) are coils that are spiral as viewed in the thickness direction.

### Clause 5

The isolation chip according to any one of clauses 1 to 4, where
the first main body (241) is a first electrode plate formed on the first upper surface (91s),
the second main body (242) is a second electrode plate formed on the second upper surface (92s), and the first electrode plate (241) and the second electrode plate (242) form a capacitor (240).

### Clause 6

The isolation chip according to any one of clauses 1 to 5, where the insulation layers (921-927) are formed from a material including Si.

### Clause 7

The isolation chip according to any one of clauses 1 to 6, where the insulation layers (921-927) each include a first insulation film (92A), formed from a material including SiN, and a second insulation film (92B), formed from a material including SiO₂.

### Clause 8

The isolation chip according to any one of clauses 1 to 7, where the insulation layers (921-927) are each formed from a material including SiO₂.

### Clause 9

The isolation chip according to any one of clauses 1 to 8, further including a third insulator (93) covering the second conductor (52, 252) and formed on the second upper surface (92s), where the third insulator includes a third upper surface (93s) facing the same direction as the second upper surface (92s).

### Clause 10

The isolation chip according to clause 9, where
the third insulator (93) includes a third wall (96C) facing the first electrode pad (81) as viewed in the thickness direction, and
the third wall (96C) is located farther from the first electrode pad (81) than the exposing recess wall (95C) is as viewed in the thickness direction.

### Clause 11

The isolation chip according to clause 10, where
the third insulator includes insulation layers (931,932), and
the third wall (96C) is formed by sidewalls (93C) of the insulation layers (931, 932).

### Clause 12

The isolation chip according to clause 10 or 11, where the third wall (96C) is stepped such that a distance to the first electrode pad (81) increases from the second upper surface (92s) toward the third upper surface.

### Clause 13

The isolation chip according to any one of claims 9 to 12, further including a second electrode pad (82) formed on the third upper surface (93s) and electrically connected to the second main body (42, 242).

### Clause 14

The isolation chip according to clause 13, further including a fourth insulator (94) covering the second electrode pad (82) and formed on the third upper surface, where the fourth insulator includes an opening that exposes a part of the second electrode pad (82).

### Clause 15

The isolation chip according to clause 14, where
the fourth insulator (94) includes a fourth wall (94C) facing the first electrode pad (81) as viewed in the thickness direction, and
the fourth wall (94C) is located farther from the first electrode pad (81) than the exposing recess wall (95C) is as viewed in the thickness direction.

### Clause 16

The isolation chip according to any one of clauses 1 to 15, further including an interconnection (53, 54) embedded in the first insulator (91) and electrically connecting the first main body (41, 241) and the first electrode pad (81).

### Clause 17

A method for manufacturing an isolation chip, the method including:
forming a first insulator (91) on a substrate upper surface (83s) of a substrate (83);
forming a first conductor (51, 251) embedded in the first insulator (91) and exposed from a first upper surface (91s) of the first insulator (91), where the first conductor includes a first main body (41, 241) and a first electrode pad (81) electrically connected to the first main body (41, 241);
forming second insulator formation layers (181-187) covering the first upper surface (91s) and the first conductor (51, 251);
forming a second conductor (52, 252) on an upper surface of an uppermost one of the second insulator formation layers (181-187), where the second conductor includes a second main body (42, 242) facing the first main body (41, 241); and
forming an exposing recess (95) to expose the first electrode pad (81) by removing parts of the second insulator formation layers (181-187), and forming a second insulator (92) including the exposing recess (95), where
the second insulator formation layers (181-187) each include a sacrificial layer (181A-187A) and a second insulation layer (921-927),
the forming the second insulator formation layers (181-187) includes forming the first sacrificial layers (181A-187A) in a manner overlapping the first electrode pad (81) in a direction perpendicular to the first upper surface (91s), and forming the second insulator formation layers (181-187) such that a distance from sidewalls (92C) of the second insulation layers (921-927), facing the first sacrificial layers (181A-187A), to the first electrode pad (81) increases from the first upper surface (91s) toward the upper surface of the uppermost one of the second insulator formation layers (187), and
parts of the second insulator formation layers (181-187) are the first sacrificial layers (181A-187A), and the first sacrificial layers (181A-187A) are collectively removed to form the exposing recess (95).

### Clause 18

The method according to clause 17, where the first sacrificial layers (181A-187A) are removed to form a stepped exposing recess wall (95C) with sidewalls (92C) of the second insulation layers (921-927).

### Clause 19

The method according to claim 17 or 18, where the first sacrificial layers (181A-187A) are formed from amorphous carbon.

### Clause 20

The method according to any one of clauses 17 to 19, further including forming a third insulator (93) in which the second conductor (52, 252) is embedded.

### Clause 21

The method according to clause 20, where the forming the third insulator (93) is performed before the forming the second insulator (92) including the exposing recess (95).

### Clause 22

The method according to clause 20 or 21, where
the forming the third insulator (93) includes forming at least one third insulator formation layer (191, 192) covering the upper surface of the uppermost one of the second insulator formation layers (187),
the third insulation formation layer (191, 192) includes a second sacrificial layer (191A, 192A) and a third insulation layer (931, 932), and
in the forming the second insulator (92), the second sacrificial layer (191A, 192A) and the first sacrificial layer (181A-187A) are collectively removed.

### Clause 23

The method according to clause 22, where the second conductor (52, 252) is formed in the third insulation layer (931) of the third insulation formation layer (191) that covers the upper surface of the uppermost one of the second insulator formation layers (187).

### Clause 24

The method according to any one of clauses 20 to 23, further including forming a second electrode pad (82) on the third insulator (93), where the second electrode pad (82) is electrically connected to the second main body (42, 242)

### Clause 25

The method according to clause 24, further including forming a fourth insulator, including an opening exposing a part of the second electrode pad (82), on the third insulator (93).

### Clause 26

A signal transmission device, including:
a die pad (101);
an isolation chip (80) disposed on the die pad (101); and
encapsulation resin (120) encapsulating the die pad (101) and the isolation chip (80), where
the isolation chip (80) includes
a substrate (83) including a substrate upper surface (83s),
a first insulator (91) formed on the substrate upper surface (83s) and including a first upper surface (91s) facing the same direction as the substrate upper surface (83s),
a first conductor (51, 251) embedded in the first insulator (91) and exposed from the first upper surface (91s),
a second insulator (92) covering the first upper surface (91s) and the first conductor (51, 251) and including a second upper surface (92s) facing the same direction as the first upper surface (91s), and
a second conductor (52, 252) disposed on the second upper surface (92s), where
the first conductor (51, 251) includes a first main body (41, 241) and a first electrode pad (81) electrically connected to the first main body (41, 241),
the second conductor (52, 252) includes a second main body (42, 242) facing the first main body (41, 241) in a thickness direction perpendicular to the first upper surface (91s),
the second insulator (92) includes insulation layers (921-927) disposed on the first upper surface (91s) in the thickness direction, and an exposing recess (95) extending through the insulation layers (921-927) and exposing the first electrode pad (81),
the exposing recess (95) includes an exposing recess wall (95C) formed by sidewalls of the insulation layers, and
the exposing recess wall (95C) is stepped such that a distance to the first electrode pad (81) increases from the first upper surface (91s) toward the second upper surface (92s).

### Clause 27

A signal transmission device, including:
a first die pad (101);
a first circuit chip (60) disposed on the first die pad (101);
a second die pad (111) insulated from the first die pad (101):
a second circuit chip (70) disposed on the second die pad (111); and
an isolation chip (80) disposed on the first die pad (101) or the second die pad (111), where
the isolation chip (80) includes
   a substrate (83) including a substrate upper surface (83s),
   a first insulator (91) formed on the substrate upper surface (83s) and including a first upper surface (91s) facing the same direction as the substrate upper surface (83s),
   a first conductor (51, 251) embedded in the first insulator (91) and exposed from the first upper surface (91s),
   a second insulator (92) covering the first upper surface (91s) and the first conductor (51, 251) and including a second upper surface (92s) facing the same direction as the first upper surface (91s), and
   a second conductor (52, 252) disposed on the second upper surface (92s),
the first conductor (51, 251) includes a first main body (41, 241) and a first electrode pad (81) electrically connected to the first main body (41, 241),
the second conductor (52, 252) includes a second main body (42, 242) facing the first main body (41, 241) in a thickness direction perpendicular to the first upper surface (91s),
the second insulator (92) includes insulation layers (921-927) disposed on the first upper surface (91s) in the thickness direction, and an exposing recess (95) extending through the insulation layers (921-927) and exposing the first electrode pad (81),
the exposing recess (95) includes an exposing recess wall (95C) formed by sidewalls of the insulation layers, and
the exposing recess wall (95C) is stepped such that a distance to the first electrode pad (81) increases from the first upper surface (91s) toward the second upper surface (92s).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

What is claimed is:

1. An isolation chip, comprising:
a substrate including a substrate upper surface;
a first insulator formed on the substrate upper surface and including a first upper surface facing the same direction as the substrate upper surface;
a first conductor embedded in the first insulator and exposed from the first upper surface;
a second insulator covering the first upper surface and the first conductor and including a second upper surface facing the same direction as the first upper surface; and
a second conductor disposed on the second upper surface, wherein
the first conductor includes a first main body and a first electrode pad electrically connected to the first main body,
the second conductor includes a second main body facing the first main body in a thickness direction perpendicular to the first upper surface,
the second insulator includes insulation layers disposed on the first upper surface in the thickness direction, and an exposing recess extending through the insulation layers and exposing the first electrode pad,
the exposing recess includes an exposing recess wall formed by sidewalls of the insulation layers, and
the exposing recess wall is stepped such that a distance to the first electrode pad increases from the first upper surface toward the second upper surface.

2. The isolation chip according to claim 1, wherein
the exposing recess is a through hole extending through the second insulator, and
the exposing recess wall surrounds the first electrode pad as viewed in the thickness direction.

3. The isolation chip according to claim 1, wherein the exposing recess includes an open side, and the exposing recess wall and the open side are located at opposite sides of the first electrode pad.

4. The isolation chip according to claim 1, wherein the first main body and the second main body are coils that are spiral as viewed in the thickness direction.

5. The isolation chip according to claim 1, wherein
the first main body is a first electrode plate formed on the first upper surface, the second main body is a second electrode plate formed on the second upper surface, and
the first electrode plate and the second electrode plate form a capacitor.

6. The isolation chip according to claim 1, wherein the insulation layers are formed from a material including Si.

7. The isolation chip according to claim 1, wherein the insulation layers each include a first insulation film, formed from a material including SiN, and a second insulation film, formed from a material including SiO₂.

8. The isolation chip according to claim 1, wherein the insulation layers are each formed from a material including SiO₂.

9. The isolation chip according to claim 1, further comprising a third insulator covering the second conductor and formed on the second upper surface, wherein the third insulator includes a third upper surface facing the same direction as the second upper surface.

10. The isolation chip according to claim 9, wherein
the third insulator includes a third wall facing the first electrode pad as viewed in the thickness direction, and
the third wall is located farther from the first electrode pad than the exposing recess wall is as viewed in the thickness direction.

11. The isolation chip according to claim 10, wherein
the third insulator includes insulation layers, and
the third wall is formed by sidewalls of the insulation layers.

12. The isolation chip according to claim 10, wherein the third wall is stepped such that a distance to the first electrode pad increases from the second upper surface toward the third upper surface.

13. The isolation chip according to claim 9, further comprising a second electrode pad formed on the third upper surface and electrically connected to the second main body.

14. The isolation chip according to claim 13, further comprising a fourth insulator covering the second electrode pad and formed on the third upper surface, wherein the fourth insulator includes an opening that exposes a part of the second electrode pad.

15. The isolation chip according to claim 14, wherein
the fourth insulator includes a fourth wall facing the first electrode pad as viewed in the thickness direction, and
the fourth wall is located farther from the first electrode pad than the exposing recess wall is as viewed in the thickness direction.

16. The isolation chip according to claim 1, further comprising an interconnection embedded in the first insulator and electrically connecting the first main body and the first electrode pad.

17. A method for manufacturing an isolation chip, the method comprising:
forming a first insulator on a substrate upper surface of a substrate;
forming a first conductor embedded in the first insulator and exposed from a first upper surface of the first insulator, wherein the first insulator includes a first main body and a first electrode pad electrically connected to the first main body;
forming second insulator formation layers covering the first upper surface and the first conductor;
forming a second conductor on an upper surface of an uppermost one of the second insulator formation layers, wherein the second conductor includes a second main body facing the first main body; and
forming an exposing recess to expose the first electrode pad by removing parts of the second insulator formation layers, and forming a second insulator including the exposing recess, wherein
the second insulator formation layers each include a sacrificial layer and a second insulation layer,
the forming the second insulator formation layers includes forming the first sacrificial layers in a manner overlapping the first electrode pad in a direction perpendicular to the first upper surface, and forming the second insulator formation layers such that a distance from sidewalls of the second insulation layers, facing the first sacrificial layers, to the first electrode pad increases from the first upper surface toward the upper surface of the uppermost one of the second insulator formation layers, and
parts of the second insulator formation layers are the first sacrificial layers, and the first sacrificial layers are collectively removed to form the exposing recess.

18. The method according to claim 17, wherein the first sacrificial layers are removed to form a stepped exposing recess wall with sidewalls of the second insulation layers.

19. The method according to claim 17, wherein the first sacrificial layers are formed from amorphous carbon.

20. The method according to claim 17, further comprising forming a third insulator, wherein the second conductor is embedded.
